(19) United States
(12) Patent Application Publication
(10) Pub. No.: US 2022/0123101 A1
(43) Pub. Date: Apr. 21, 2022

(54) HIGH DENSITY METAL-INSULATOR-METAL CAPACITOR

(71) Applicant: QUALCOMM Incorporated, San Diego, CA (US)

(72) Inventors: Xia LI, San Diego, CA (US); Jun YUAN, San Diego, CA (US); Haining YANG, San Diego, CA (US); Bin YANG, San Diego, CA (US)

(21) Appl. No.: 17/074,026

(22) Filed: Oct. 19, 2020

(51) Int. Cl. H01L 49/02; H01L 23/522

(52) U.S. Cl. CPC H01L 28/40; H01L 23/5223

(57) ABSTRACT

Disclosed are examples of 3D metal-insulator-metal (MIM) capacitor structures, e.g., in semiconductor packages. The disclosed 3D MIM capacitors provide high capacitance in small areas. As such, the disclosed 3D MIM capacitors may be used as decoupling capacities for high performance computing (HPC) processors.

### FIELD OF DISCLOSURE

This disclosure relates generally to capacitors, and more specifically, but not exclusively, to high density metal-insulator-metal (MIM) capacitors and fabrication techniques thereof.

### BACKGROUND

High performance computation (HPC) processors, such as those for artificial intelligence (AI), are large and require capacitors for power decoupling to improve power IR drop for high performance high frequency computations. Multiple MIM capacitors can be used to decouple the power supply lines (Vdd) for high performance. However, conventional MIM capacitors may be insufficient to provide the necessary decoupling performance.

Accordingly, there is a need for systems, apparatus, and methods that overcome the deficiencies of conventional capacitor configurations including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary 3D metal-insulator-metal (MIM) capacitor is disclosed. The 3D MIM capacitor may comprise first and second vias defining a trench portion therebetween. The 3D MIM capacitor may also comprise a first plate in the trench portion and coupled with the first via at a first side of the trench portion. The first plate may have a first serpentine shape. The 3D MIM capacitor may further comprise a second plate in the trench portion and coupled with the second via at a second side of the trench portion. The second plate may have a second shape such that there is a first serpentine gap between the first and second plates. The first serpentine gap may be substantially parallel with the first serpentine shape. The 3D MIM capacitor may yet comprise a first capacitor dielectric in the first serpentine gap between the first and second plates. The first via may penetrate through the first plate and/or the second via may penetrate through the second plate.

A method of fabricating a 3D metal-insulator-metal (MIM) capacitor is disclosed. The method may comprise forming first and second vias defining a trench portion therebetween. The method may also comprise forming a first plate in the trench portion. The first plate may be coupled with the first via at a first side of the trench portion and may have a first serpentine shape. The method may further comprise forming a second plate in the trench portion. The second plate may be coupled with the second via at a second side of the trench portion and may have a second shape such that there is a first serpentine gap between the first and second plates. The first serpentine gap may be substantially parallel with the first serpentine shape. The method may yet comprise disposing a first capacitor dielectric to fill in the first serpentine gap between the first and second plates. The first via may penetrate through the first plate and/or the second via may penetrate through the second plate.

Another exemplary 3D metal-insulator-metal (MIM) capacitor is disclosed. The 3D MIM capacitor may comprise first, second, third, and fourth vias respectively located on first, second, third, and fourth sides of the 3D MIM capacitor. The first, second, third, and fourth sides may be distinct sides of the 3D MIM capacitor. The first and second sides may be opposite sides, and the third and fourth sides may be opposite sides. The 3D MIM capacitor may also comprise at least four plates within the first, second, third, and fourth sides of the 3D MIM capacitor. The at least four plates may comprise first, second, fifth, and sixth plates. The first plate may be coupled to the first via. The second plate may be above the first plate and coupled to the second via. The fifth plate may be above the second plate and coupled to the third via. The sixth plate may be above the fifth plate and coupled to the fourth via. The 3D MIM capacitor may further comprise at least two capacitor dielectrics within the first, second, third, and fourth sides of the 3D MIM capacitor. The at least two capacitor dielectrics may comprise first and fifth capacitor dielectrics. The first capacitor dielectric may be sandwiched between the first and second plates. The fifth capacitor dielectric may be sandwiched between the fifth and sixth plates. The first and third vias may be coupled to a first common source and the second and fourth vias may be coupled to a second common source.

Another method of fabricating a 3D metal-insulator-metal (MIM) capacitor is disclosed. The method may comprise forming first, second, third, and fourth vias respectively located on first, second, third, and fourth sides of the 3D MIM capacitor. The first, second, third, and fourth sides may be distinct sides of the 3D MIM capacitor. The first and second sides may be opposite sides, and the third and fourth sides may be opposite sides. The method may also comprise forming at least four plates within the first, second, third, and fourth sides of the 3D MIM capacitor. The at least four plates may comprise first, second, fifth, and sixth plates. The first plate may be coupled to the first via. The second plate may be above the first plate and coupled to the second via. The fifth plate may be above the second plate and coupled to the third via. The sixth plate may be above the fifth plate and coupled to the fourth via. The method may further comprise forming at least two capacitor dielectrics within the first, second, third, and fourth sides of the 3D MIM capacitor. The at least two capacitor dielectrics may comprise first and fifth capacitor dielectrics. The first capacitor dielectric may be sandwiched between the first and second plates. The fifth capacitor dielectric may be sandwiched between the fifth and sixth plates. The first and third vias may be coupled to a first common source and the second and fourth vias may be coupled to a second common source.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIGS. 1A-1B illustrates examples of conventional MIM capacitors.

FIGS. 2A-2B and 3A-3E illustrate examples of MIM capacitors in accordance with one or more aspects of the disclosure.

FIGS. 4A-4F and 5A-5H illustrate examples of stages of fabricating MIM capacitors in accordance with one or more aspects of the disclosure.

FIGS. 6A-6B, 7, 8A-8D, and 9 illustrate flow charts of example methods of fabricating MIM capacitors in accordance with one or more aspects of the disclosure.

FIG. 10 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

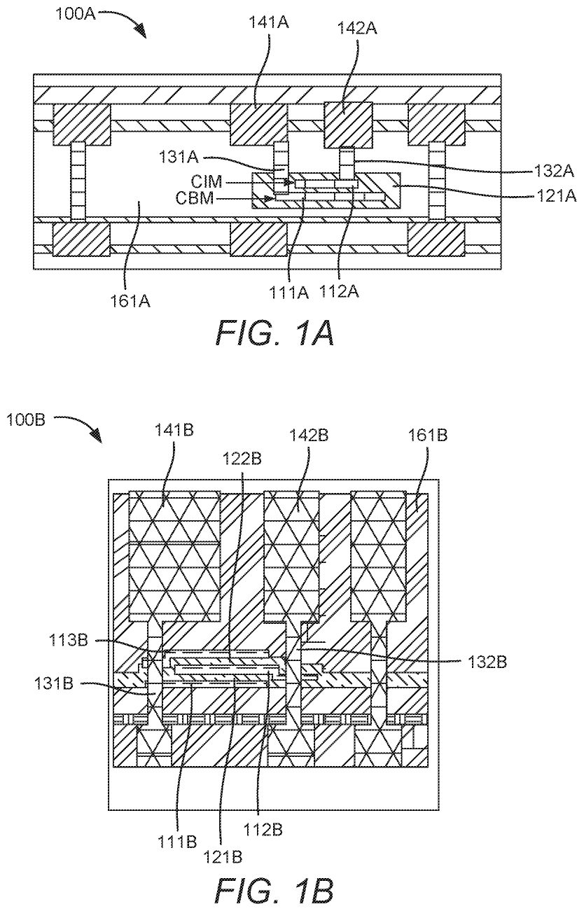

FIG. 1A illustrates an example of a conventional metal-insulator-metal (MIM) capacitor structure 100A. FIG. 1A illustrates an example of a two-plate MIM capacitor comprising a first plate 111A, a second plate 112A, and a capacitor dielectric 121A between the first and second plates 111A, 112A. An interlayer dielectric (ILD) 161A covers the first and second plates 111A, 112A and the capacitor dielectric 121A. The MIM capacitor 100A also includes first and second vias 131A, 132A respectively coupled to the first and second plates 111A, 112A. First and second contacts 141A, 142A are respectively coupled to the first and second vias 131A, 132A.

FIG. 1B illustrates example of another conventional MIM capacitor structure 100B, which is an example of a three-plate MIM capacitor comprising first, second, and third plates 111B, 112B, and 113B. The three-plate MIM capacitor 100B can provide higher capacitance than the two-plate MIM capacitor 100A. The three-plate MIM capacitor 100B also comprises a first capacitor dielectric 121B between the first and second plates 111B, 112B, and a second capacitor dielectric 122B between the second and third plates 112B, 113B. An ILD 161B covers the first, second, and third plates 111B, 112B, 113B and the first and second capacitor dielectrics 121B, 122B. The MIM capacitor structure 100B also includes a first via 131A coupled to the first and third plates 111B, 113B, and a second via 132B coupled to the second plate 112B. First and second contacts 141B, 142B are respectively coupled to the first and second vias 131B, 132B.

As indicated above, processors use capacitors for power decoupling to improve power IR drop for high performance high frequency computations. But for many modern HPC processors, the conventional MIM capacitors such as capacitors 100A, 100B of FIGS. 1A and 1B still may be insufficient to provide the necessary decoupling performance, i.e., does not provide sufficient protection against voltage droops.

In accordance with the various aspects disclosed herein, to address issues associated with conventional interconnect structures, it is proposed to provide MIM capacitors with increased capacitance. As a result, modern HPC processors may be protected against severe voltage droops.

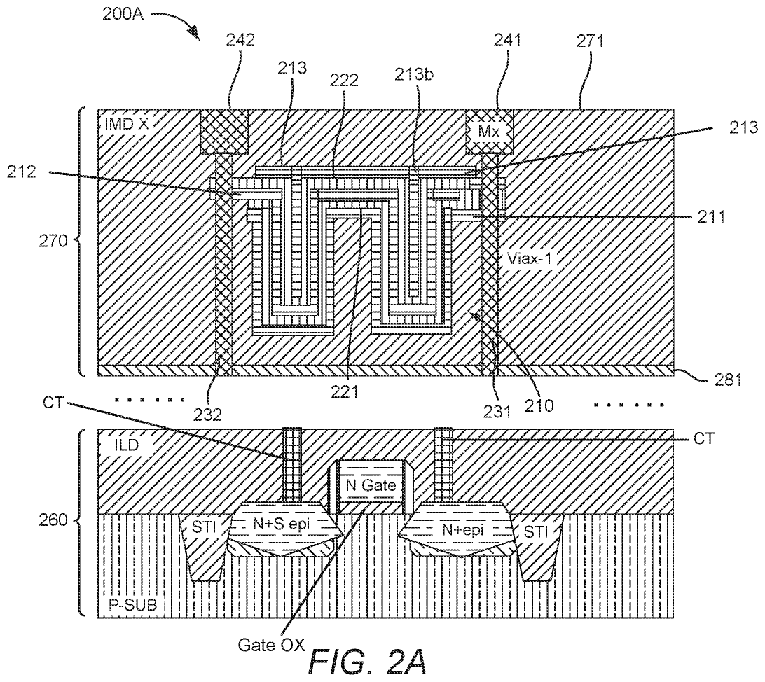

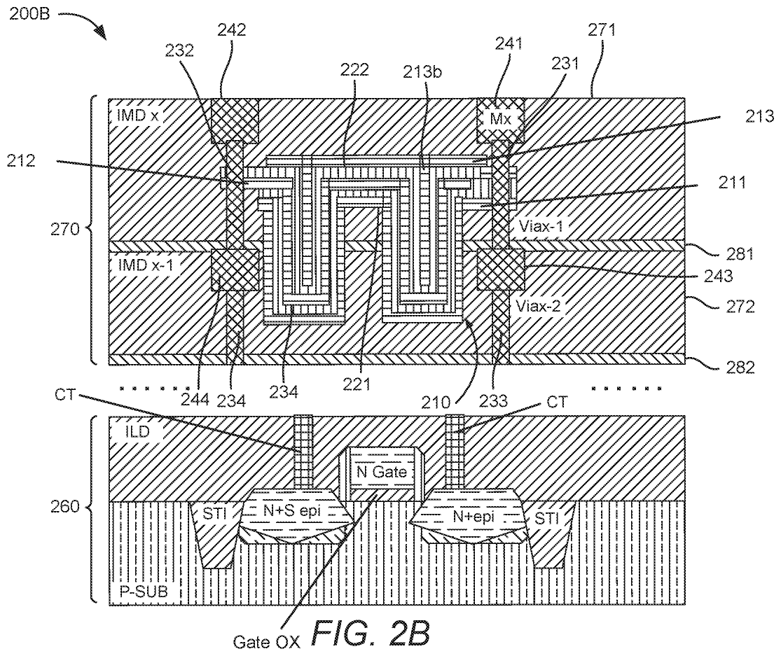

FIG. 2A illustrates an example of a 3D MIM capacitor 200A in accordance with one or more aspects of the disclosure. The 3D MIM capacitor 200A may be formed in a metallization layer 270 which may comprise an etch stop layer 281 and an intermetal dielectric (IMD) 271 on the etch stop layer 281. In this context, “on” may be synonymous with “in contact with”. The metallization layer 270 may be viewed as a back end of line (BEOL) layer where interconnects are formed. The metallization layer 270 may be differentiated from a device layer 260, which may be viewed a front end of line (FEOL) layer which comprises active components such as transistors. As seen, there can be multiple metallization layers 270 above the device layer 260.

The 3D MIM capacitor 200A may comprise first and second vias 231, 232 formed in the metallization layer 270, e.g., within the IMD 271 and the etch stop layer 281. Lower surfaces of the first and second vias 231, 232 may be substantially coplanar with lower surface of the etch stop layer 281. That is, the lower surfaces of the first and second vias 231, 232 may be exposed, i.e., not covered by the etch stop layer 281. The area between the first and second vias 231, 232 may be referred to as a trench portion 210.

First and second contacts 241, 242 may be formed on and coupled with the first and second vias 231, 232, respectively within the IMD 271. The first contact 241 (and hence the first via 231) may be coupled to a first source (e.g., Vss) and the second contact 242 (and hence the second via 232) may be coupled to a second source (e.g., Vdd). Top surfaces of the first and second contacts 241, 242 may be substantially coplanar with an upper surface of the IMD 271. In an aspect, the first contact 241 and the first via 231 may be integrally formed from a same metal material (e.g., Cu). The second contact 242 and the second via 232 may also be integrally formed.

The 3D MIM capacitor 200A may a number of plates (two or more) and a number of capacitor dielectrics (one or more). FIG. 2A illustrates a MIM capacitor that comprises first, second, and third plates 211, 212, 213 (three plates) and first and second capacitor dielectrics 221, 222 (two capacitor dielectrics) all in the trench portion 210. The first plate 211 may be formed in the trench portion 210, the first capacitor dielectric 221 may be formed on the first plate 211, the second plate 212 may be formed on the first capacitor dielectric 221, the second capacitor dielectric 222 may be formed on the second plate 212, and the third plate 213 may be formed on the second capacitor dielectric 222.

It should be noted that terms or phrases such as “lower”, “upper”, “left”, “right”, “below”, “above”, “horizontal, “vertical”, etc. are used for convenience. Unless otherwise specifically indicated, such terms/phrased are not intended to indicate absolute orientations or directions. Also as indicated, terms “on” and “in contact with” may be used synonymously unless otherwise specifically indicated.

The first plate 211 may be coupled with the first via 231 at a first side (e.g., right side) of the trench portion 210, the second plate 212 may be coupled with the second via 232 at a second side (e.g., left side) of the trench portion 210. The first plate 211 may have a first serpentine shape. The second plate 212 may have a second shape such that there is a first serpentine gap between the first and second plates 211, 212, in which the first serpentine gap is substantially parallel with the first serpentine shape of the first plate 211. In an aspect, the second shape may be a second serpentine shape that is also substantially parallel with the first serpentine shape. The first capacitor dielectric 221 may be in the first serpentine gap between the first and second plates 211, 212.

The serpentine shapes increase surface areas of the first and second plates 211, 212 and of the first capacitor dielectric 221. These factors enable the capacitance of the 3D MIM capacitor 200A to be increased, which is desirable in applications such as minimizing voltage droops.

The third plate 213 may be coupled with the first via 231 at the first side of the trench portion 210. The third plate 213 may have a third shape such that there is a second serpentine gap between the second and third plates. For example, the second serpentine gap may be substantially parallel with the second serpentine shape of the second plate 212. In this instance, the third plate 213 may have one or more third extensions 213b that extend into one or more wells formed by the second plate 212. The second capacitor dielectric 222 may be in the second serpentine gap between the second and third plates 212, 213. The second capacitor dielectric 222 and the third plate 213 provide additional capacitance to the 3D MIM capacitor 200A.

In an aspect, the first capacitor dielectrics 221 and/or the second capacitor dielectric 222 may be high-k dielectrics while the IMD 271 may be a low-k dielectric. Also, the first via 231 may penetrate through all plates, including the first and third plates 211, 213, coupled to the first via 231. Similarly, the second via 232 may penetrate through all plates, including the second plate 212, coupled to the second via 232.

FIG. 2B illustrates another example of a 3D MIM capacitor 200B in accordance with one or more aspects of the disclosure. The 3D MIM capacitor 200B may be very similar to the 3D MIM capacitor 200A of FIG. 2A. One difference between them is that the 3D MIM capacitor 200B of FIG. 2B may be formed in multiple metallization layers 270. For example, the MIM capacitor 200B may be formed in a first metallization layer comprising a first IMD 271 on a first etch stop layer 281, and in second metallization layer comprising a second IMD 272 on a second etch stop layer 282. Third and fourth contacts 243, 244 may be formed respectively on third and fourth vias 233, 234. The third contact 243 and the third via 233 may be coupled with the first contact 241 and the first via 231. The fourth contact 244 and the fourth via 234 may be coupled with the second contact 242 and the second via 232. By forming the 3D MIM capacitor 200B in multiple metallization layers 270, surface areas of the plates and capacitor dielectrics can be increased even further, which means that the capacitances can also be increased.

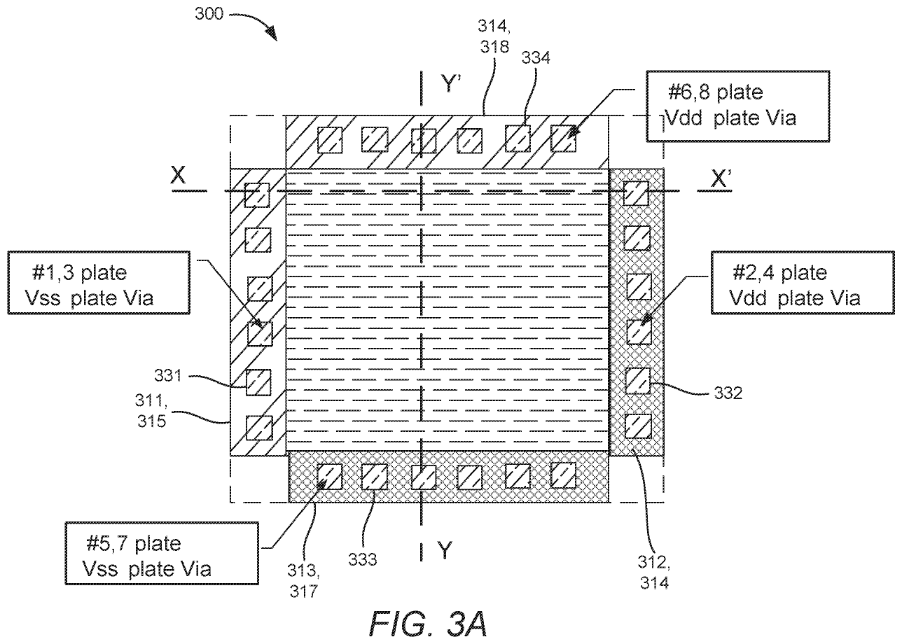

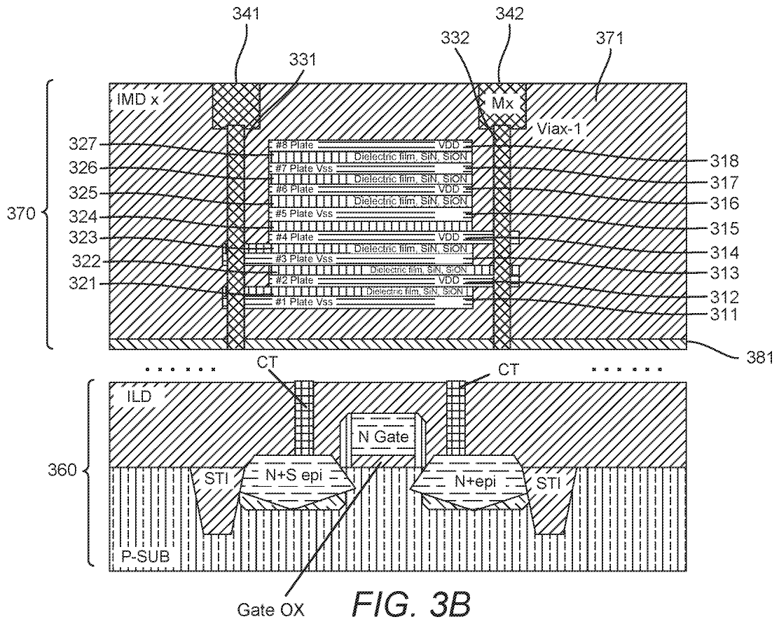

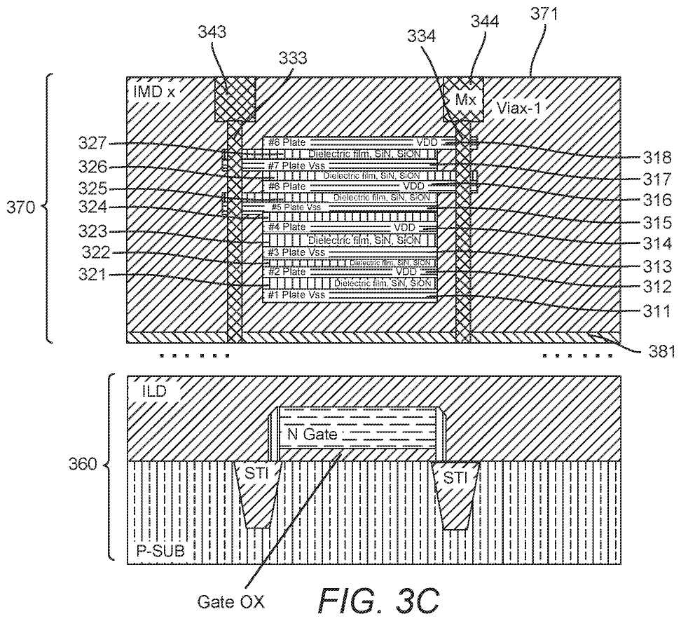

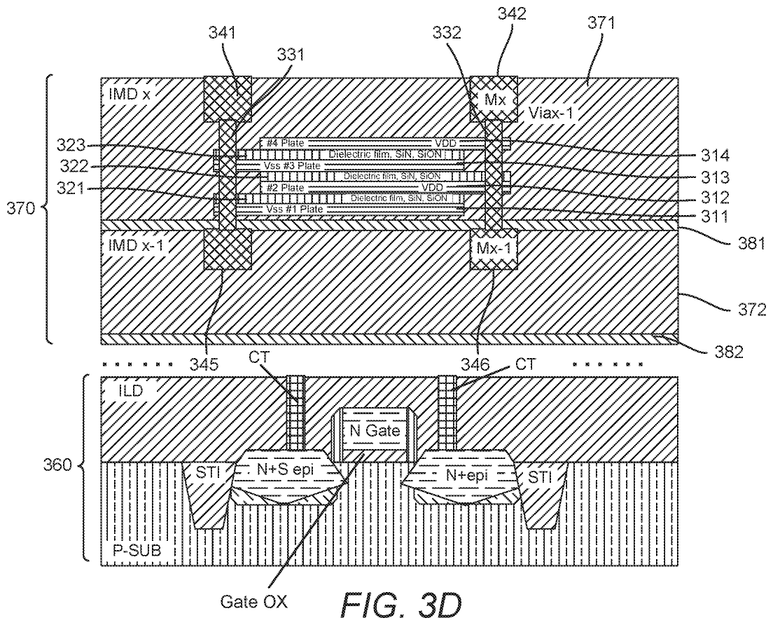

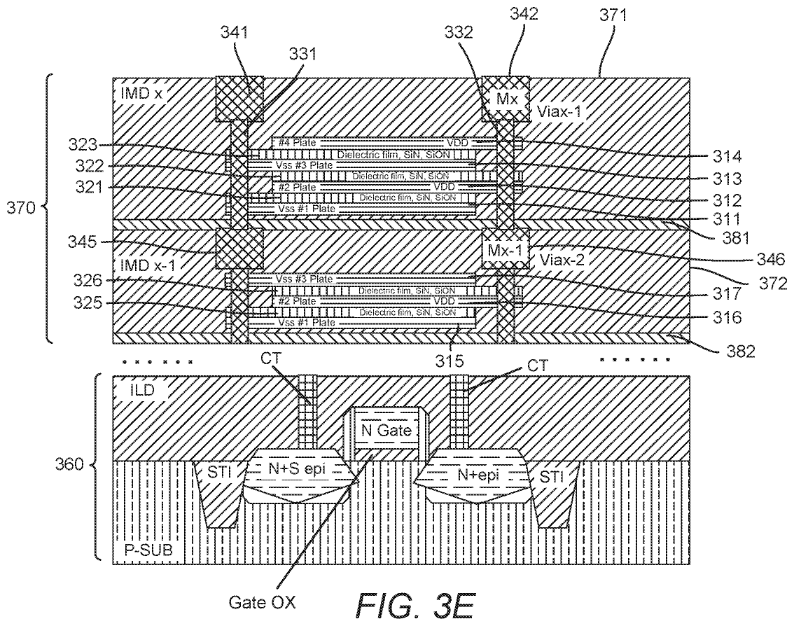

FIGS. 3A-3C illustrate an example of a MIM capacitor 300 in accordance with one or more aspects of the disclosure. FIG. 3A illustrates a top view, FIG. 3B illustrates a cross-sectional view along line X-X′ of FIG. 3A, and FIG. 3C illustrates a cross-sectional view along line Y-Y′ of FIG. 3A. The 3D MIM capacitor 300 may be formed in a metallization layer 370 which may comprise an etch stop layer 381 and an IMD 371 on the etch stop layer 381. The metallization layer 370 may be viewed as a BEOL layer where interconnects are formed. The metallization layer 370 may be differentiated from a device layer 360, which may be viewed a FEOL layer which comprises active components such as transistors. There can be multiple metallization layers 370 above the device layer 360.

As seen in FIG. 3A, vias may be located on more than two sides of the MIM capacitor 300. For example, first vias 331 may be located on a first side (e.g. left side), second vias 332 may be located on a second side (e.g., right side), third vias 333 may be located on a third side (e.g., lower side), and fourth vias 334 may be located on a fourth side (e.g., upper side). The first and third sides may be opposite sides, and the second and fourth sides may be opposite sides.

The first, second, third, and fourth vias 331, 332, 333, 334 may be formed in the metallization layer 370, e.g., within the IMD 371 and the etch stop layer 381. Lower surfaces of the first second, third, and fourth vias 331, 332, 333, 334 may be substantially coplanar with lower surface of the etch stop layer 381.

First second, third, and fourth contacts 341, 342, 343, 344 may respectively be formed on and coupled with the first second, third, and fourth vias 331, 332, 333, 334 within the IMD 371. The first and third contacts 341, 343 (and hence the first and third vias 331, 333) may be coupled to a first common source (e.g., Vss) and the second and fourth contacts 342, 344 (and hence the second and fourth vias 332, 334) may be coupled to a second common source (e.g., Vdd).

Top surfaces of the first second, third, and fourth contacts 341, 342, 343, 344 may be substantially coplanar with an upper surface of the IMD 371. In an aspect, the first contact 341 and the first via 331 may be integrally formed from a same metal material (e.g., Cu), the second contact 342 and the second via 332 be integrally formed, the third contact 343 and the third via 333 may be integrally formed, and the fourth contact 344 and the fourth via 334 may be integrally formed.

The 3D MIM capacitor 300 may also comprise a plurality of plates and a plurality of capacitor dielectrics within the four sides. The illustrated MIM capacitor 300 may comprise eight plates (e.g., first through eighth plates 311-318) and seven capacitor dielectrics (e.g., first through seventh capacitor dielectrics 321-327). It should be noted that this is merely an example, i.e., the numbers of plates and capacitor dielectrics are not so limited.

As seen, the plates and capacitor dielectrics may be stacked on one another within the IMD 371 as follows: the first plate 311, the first capacitor dielectric 321, the second plate 312, the second capacitor dielectric 322, the third plate 313, the third capacitor dielectric 323, the fourth plate 314, the fourth capacitor dielectric 324, the fifth plate 315, the fifth capacitor dielectric 325, the sixth plate 316, the sixth capacitor dielectric 326, the seventh plate 317, the seventh capacitor dielectric 327, and the eighth plate 318.

The first and third plates 311, 313 may be coupled to the first via 331 on the first side, and the second and fourth plates 312, 314 may be coupled to the second via 332 on the second side opposite the first side (see FIG. 3B). The fifth and seventh plates 315, 317 may be coupled to the third via 333 on the third side, and the sixth and eighth plates 316, 318 may be coupled to the fourth via 334 on the fourth side opposite the third side (see FIG. 3C).

One of the features of the illustrated 3D MIM capacitor 300 is that at least one plate may be coupled to each of the first, second, third, and fourth vias 331, 332, 333, 334 on each side. This means that the number of plates may be at least four. In FIGS. 3A-3C, the at least four plates may comprise the first plate 311 coupled to the first via 331, the second plate 312 coupled to the second via 332, the fifth plate 315 coupled to the third via 333, and the sixth plate 316 coupled to the fourth via 334. As seen, the second plate 312 may be above the first plate 311, the fifth plate 315 may be above the second plate 312, and the sixth plate 316 may be above the fifth plate 315.

This also implies that the number of capacitor dielectrics may be at least two. For example, the first capacitor dielectric 321 may be sandwiched between the first and second plates 311, 312 (e.g., in contact with the first and second plates 311, 312) and the fifth capacitor dielectric 325 may be sandwiched between the fifth and sixth plates 315, 316. By fitting many plates (e.g., at least four) and capacitor dielectrics, the capacitance of the MIM capacitor 300 may be enhanced.

Of course, the capacitance can be increased by providing more plates and capacitor dielectrics. For example, the 3D MIM capacitor 300 embodiment illustrated in FIGS. 3A-3C may comprise at least four additional plates, which may include the third plate 313 coupled to the first via 331, the fourth plate 314 coupled to the second via 332, a seventh plate 317 coupled to the third via 333, and an eighth plate 318 coupled to the fourth via 334. The third plate 313 may be above the second plate 312, the fourth plate 314 may be between the third and fifth plates 313, 315, the seventh plate 317 may be above the sixth plate 316, and the eighth plate 318 may be above the seventh plate 317.

There may also be at least five additional capacitor dielectrics. These may include the second capacitor dielectric 322 sandwiched between the second and third plates 312, 313, the third capacitor dielectric 323 sandwiched between the third and fourth plates 313, 314, the fourth capacitor dielectric 324 sandwiched between the fourth and fifth plates 314, 315, the sixth capacitor dielectric 326 sandwiched between the sixth and seventh plates 316, 317, and the seventh capacitor dielectric 327 sandwiched between the seventh and eighth plates 317, 318.

In an aspect, some or all of the capacitor dielectrics 321-327 may be high-k dielectrics while the IMD 371 may be a low-k dielectric. The first via 331 may penetrate through all plates, including the first and third plates 311, 313, coupled to the first via 331. The second via 332 may penetrate through all plates, including the second and fourth plates 312, 314, coupled to the second via 232. The third via 333 may penetrate through all plates, including the fifth and seventh plates 315, 317, coupled to the third via 333. The fourth via 334 may penetrate through all plates, including the sixth and eighth plates 316, 318, coupled to the fourth via 334. One advantage of locating the vias in multiple sides is that the number of plates penetrated through by each via can be minimized. For example, even though there are eight plates in the illustrated MIM capacitor, each via only penetrates two of the eight plate layers.

FIGS. 3D and 3E illustrate other examples of 3D MIM capacitors in accordance with one or more aspects of the disclosure. The 3D MIM capacitor in these figures may be similar to the 3D MIM capacitor of FIGS. 3A-3C. One of the differences is that FIGS. 3D, 3E illustrate the MIM capacitors being formed in multiple metallization layers 370, and the number of plates and capacitor dielectrics may differ. For example, a second metallization layer may include an etch stop layer 382 and an IMD 372 on the etch stop layer. Contacts 345, 346 may be respectively coupled to first and second vias 331, 332. Also, while not specifically shown, different metallization layers 370 may comprise plates coupled with vias from one set of opposite sides (e.g., one metallization layer may comprise plates coupled to vias of first and second sides, and another metallization may comprise plates coupled to vias of third and fourth sides).

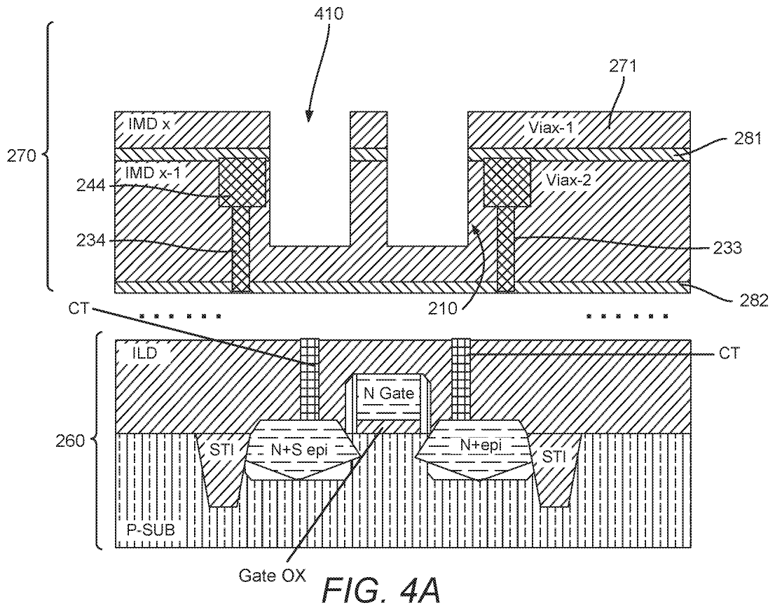

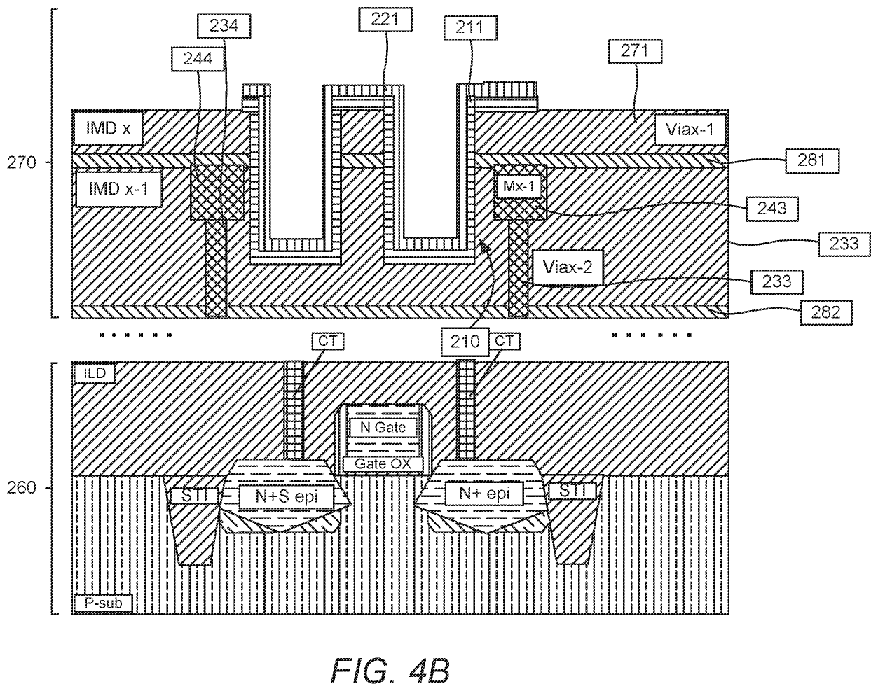

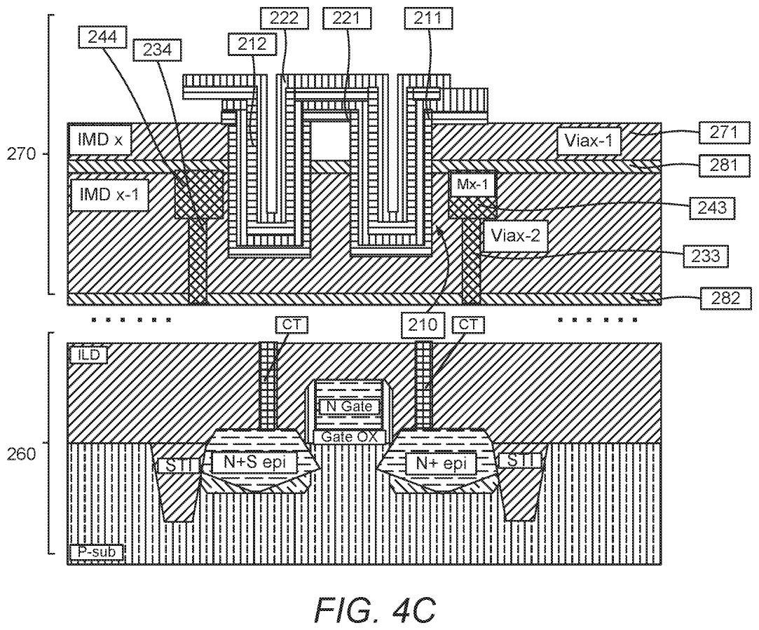

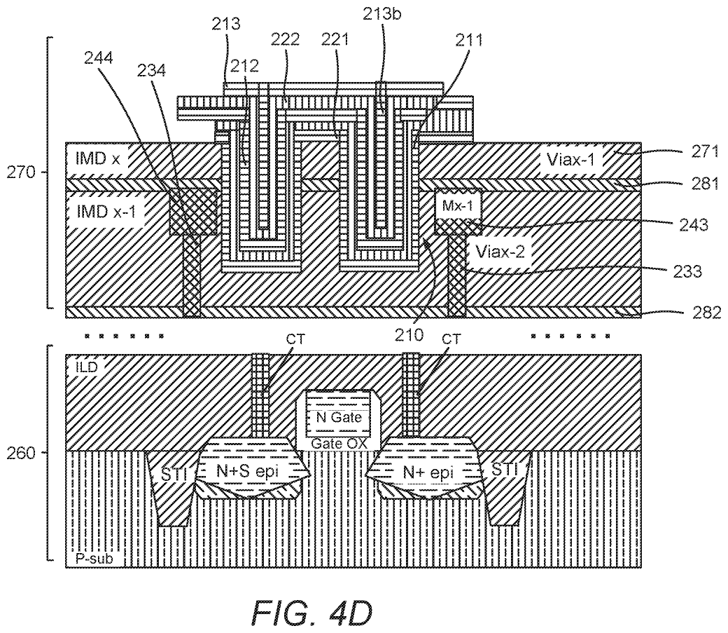

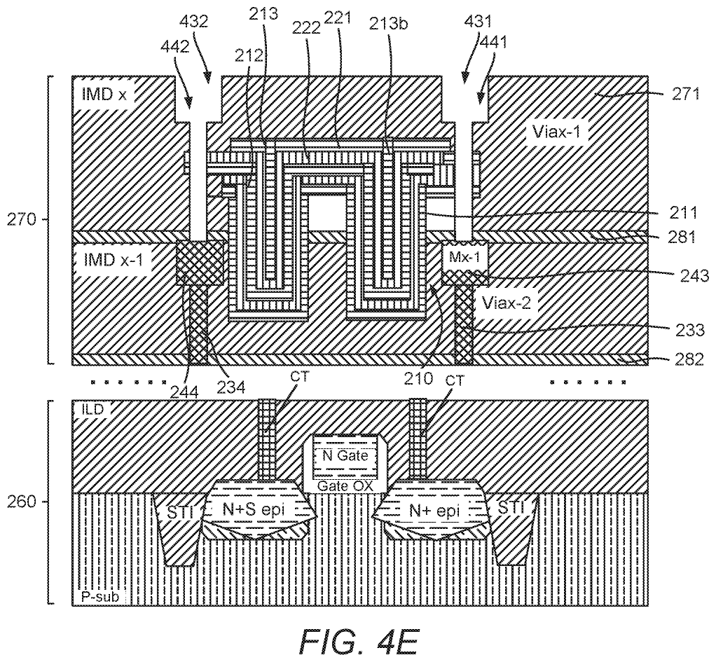

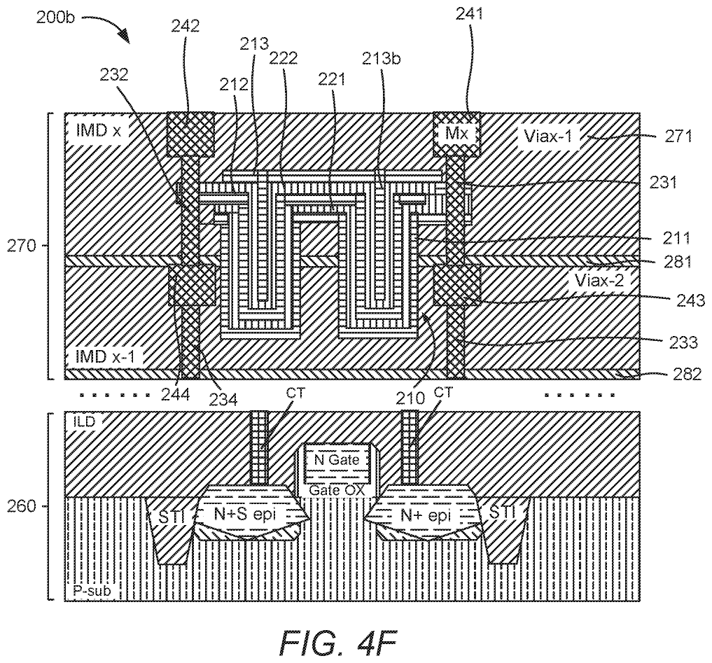

FIGS. 4A-4F illustrate example stages of fabricating a 3D MIM capacitors such as 3D MIM capacitor 200B illustrated in FIG. 2B, in accordance with one or more aspects of the disclosure. As will be made clear below, the illustrated stages may also apply to the fabrication of 3D MIM capacitor 200A of FIG. 2A.

FIG. 4A illustrates a stage in which one or more metallization layers 270 (e.g., IMDs and etch stop layers) may be etched to form a trench pattern 410. FIG. 4A shows multiple (e.g., two) metallization layers 270 being etched, which can apply to a stage of fabricating the 3D MIM capacitor 200B of FIG. 2B. Alternatively, one metallization layer 270 may be etched, which applies a stage of fabricating the 3D MIM capacitor 200A of FIG. 2A. The remaining stages may be same or similar for both capacitors 200A, 200B.

FIG. 4B illustrates a stage in which a first plate layer may be deposited on the IMD 271 including in the trench pattern 410. A first capacitor dielectric layer may be deposited on the first plate layer. The first plate layer may be a layer of metal and the first capacitor dielectric layer may be a high-k dielectric layer. The deposited first plate layer and the first capacitor dielectric layer may be patterned to form the first plate 211 and the first capacitor dielectric 221.

FIG. 4C illustrates a stage in which a second plate layer may be deposited on the IMD 271 including on the first capacitor dielectric 221. A second capacitor dielectric layer may be deposited on the first plate layer. The second plate layer may be a layer of metal same or different from the first plate layer. The second capacitor dielectric layer may be a high-k dielectric layer. The second capacitor dielectric layer may be same or different from the first capacitor dielectric layer. The deposited second plate layer and the second capacitor dielectric layer may be patterned to form the second plate 212 and the second capacitor dielectric 222.

FIG. 4D illustrates a stage in which a third plate layer may be deposited on the IMD 271 including on the second capacitor dielectric 222. The third plate layer may be a layer of metal same or different from the first plate layer and/or the second plate layer. The deposited third plate layer may be patterned to form the third plate 212.

FIG. 4E illustrates a stage in which more IMD 271 may be deposited to cover the first, second, and third plates 211, 212, 213 and the first and second capacitor dielectrics 221, 222. Thereafter, the IMD 271 may be etched to form first and second via patterns 431, 432 and first and second contact patterns 441, 442. Note that the first and second via patterns 431, 432 may be patterned through the first, second, and third plates 211, 212, 213.

FIG. 4F illustrates a stage in which the first and second via patterns 431, 432 and the first and second contact patterns 441, 442 may be filled with metal to form the first and second vias 231, 232 and the first and second contacts 241, 242.

While not specifically shown, note that it is relatively straight forward to modify the process illustrated in FIGS. 4A-4F to fabricate MIM capacitors with any number of plates (e.g., more than three) and any number of capacitor dielectrics (e.g., more than two) having serpentine-like shapes.

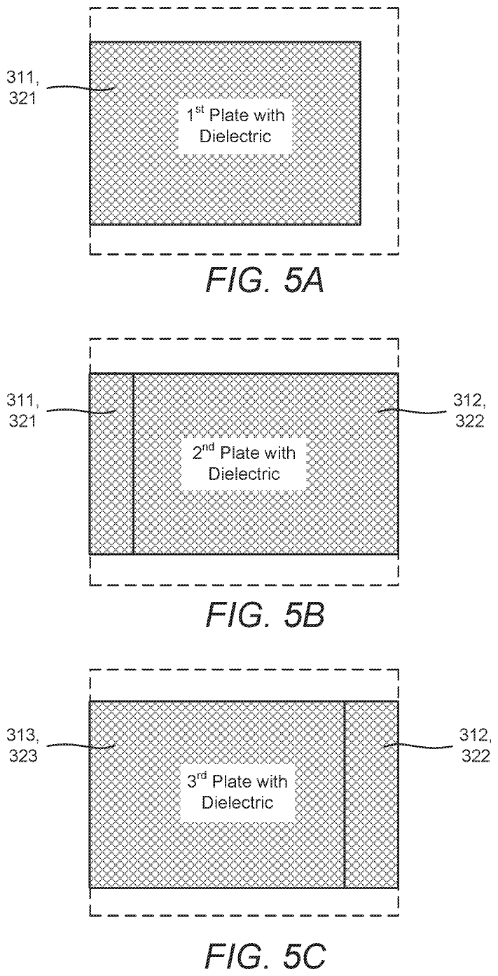

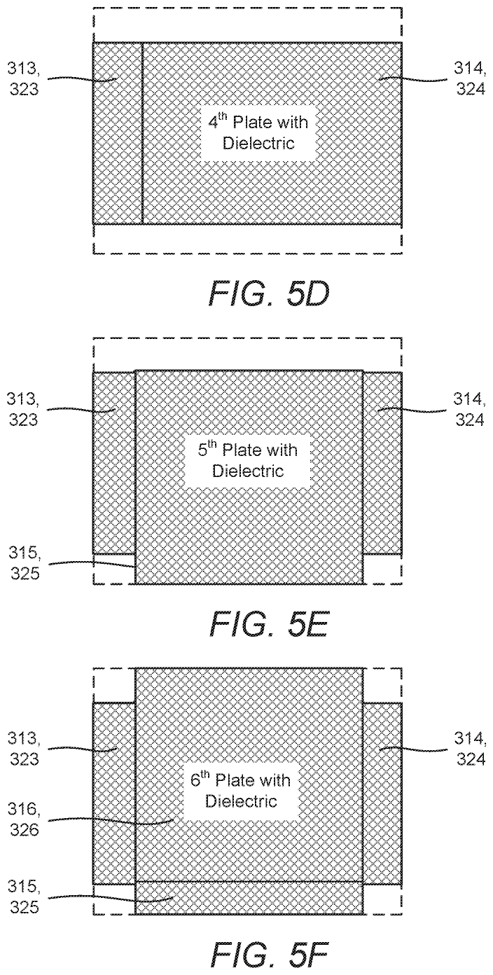

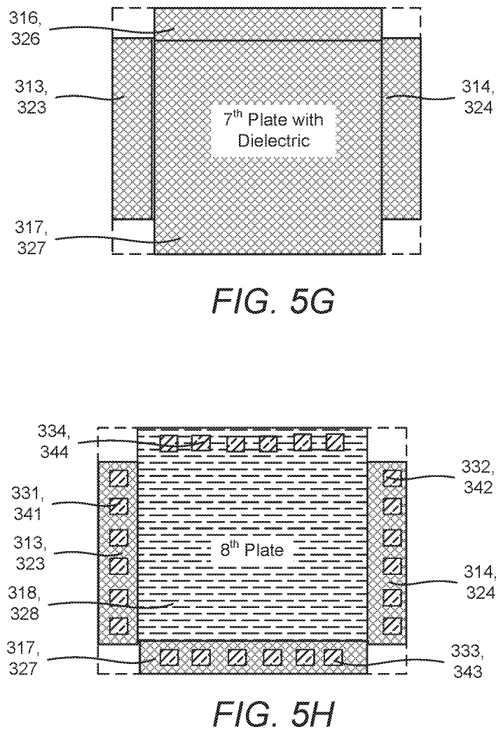

FIGS. 5A-5H illustrate example stages of fabricating a 3D MIM capacitors such as 3D MIM capacitor 300 illustrated in FIGS. 3A-3C, in accordance with one or more aspects of the disclosure. FIGS. 5A-5H illustrate top views of the stages. In these figures, the dashed rectangle may represent an outline of a trench pattern of the MIM capacitor.

FIG. 5A illustrates a stage in which a first plate layer may be deposited within the trench pattern in a metallization layer 370. The first plate layer may be a metal layer. A first capacitor dielectric layer may be deposited on the first plate layer. The first capacitor dielectric layer may be a high-k dielectric layer. The deposited first plate layer and the first capacitor dielectric layer may be patterned to form the first plate 311 and the first capacitor dielectric 321. As seen, the first plate 311 and the first capacitor dielectric 321 may be formed to cover an edge of the first side (e.g., left side) corresponding to where the first vias 331 will be located.

FIG. 5B illustrates a stage in which a second plate layer may be deposited on the first capacitor dielectric 321. The second plate layer may be a metal layer same or different from the first plate layer. A second capacitor dielectric layer may be deposited on the second plate layer. The second capacitor dielectric layer may be a high-k dielectric layer same or different from the first capacitor dielectric layer. The deposited second plate layer and the second capacitor dielectric layer may be patterned to form the second plate 312 and the second capacitor dielectric 322. As seen, the second plate 312 and the second capacitor dielectric 322 may be formed to cover an edge of the second side (e.g., right side) corresponding to where the second vias 332 will be located. In this top view, the edge of the first side of the first capacitor dielectric 321 may be viewable and the rest may be obscured by the second capacitor dielectric 322.

FIG. 5C illustrates a stage in which a third plate layer may be deposited on the second capacitor dielectric 322. The third plate layer may be a metal layer same or different from the first and/or the second plate layer. A third capacitor dielectric layer may be deposited on the third plate layer. The third capacitor dielectric layer may be a high-k dielectric layer same or different from the first and/or the second capacitor dielectric layer. The deposited third plate layer and the third capacitor dielectric layer may be patterned to form the third plate 313 and the third capacitor dielectric 323. As seen, the third plate 313 and the third capacitor dielectric 323 may be formed to cover the edge of the first side. In this top view, all of the first capacitor dielectric 321 may be obscured. Also, the edge of the second side of the second capacitor dielectric 322 may be viewable and the rest may be obscured by the third capacitor dielectric 323.

FIG. 5D illustrates a stage in which a fourth plate layer may be deposited on the third capacitor dielectric 323. The fourth plate layer may be a metal layer same or different from the first, second, and/or the third plate layer. A fourth capacitor dielectric layer may be deposited on the fourth plate layer. The fourth capacitor dielectric layer may be a high-k dielectric layer same or different from the first, second, and/or the third capacitor dielectric layer. The deposited fourth plate layer and the fourth capacitor dielectric layer may be patterned to form the fourth plate 314 and the fourth capacitor dielectric 324. As seen, the fourth plate 314 and the fourth capacitor dielectric 324 may be formed to cover the edge of the second side. In this top view, all of the second capacitor dielectric 322 may be obscured. Also, the edge of the first side of the third capacitor dielectric 323 may be viewable and the rest may be obscured by the fourth capacitor dielectric 324.

FIG. 5E illustrates a stage in which a fifth plate layer may be deposited on the fourth capacitor dielectric 324. The fifth plate layer may be a metal layer same or different from the first, second, third, and/or the fourth plate layer. A fifth capacitor dielectric layer may be deposited on the fifth plate layer. The fifth capacitor dielectric layer may be a high-k dielectric layer same or different from the first, second, third, and/or the fourth capacitor dielectric layer. The deposited fifth plate layer and the fifth capacitor dielectric layer may be patterned to form the fifth plate 315 and the fifth capacitor dielectric 325. As seen, the fifth plate 315 and the fifth capacitor dielectric 325 may be formed to cover the edge of the third side corresponding to where the third vias 333 will be located.

FIG. 5F illustrates a stage in which a sixth plate layer may be deposited on the fifth capacitor dielectric 325. The sixth plate layer may be a metal layer same or different from the first, second, third, fourth, and/or the fifth plate layer. A sixth capacitor dielectric layer may be deposited on the sixth plate layer. The sixth capacitor dielectric layer may be a high-k dielectric layer same or different from the first, second, third, fourth, and/or the fifth capacitor dielectric layer. The deposited sixth plate layer and the sixth capacitor dielectric layer may be patterned to form the sixth plate 316 and the sixth capacitor dielectric 326. As seen, the sixth plate 316 and the sixth capacitor dielectric 326 may be formed to cover the edge of the fourth side corresponding to where the fourth vias 334 will be located. In this top view, the edge of the third side of the fifth capacitor dielectric 325 may be viewable and the rest may be obscured by the sixth capacitor dielectric 326.

FIG. 5G illustrates a stage in which a seventh plate layer may be deposited on the sixth capacitor dielectric 326. The seventh plate layer may be a metal layer same or different from the first, second, third, fourth, fifth, and/or the sixth plate layer. A seventh capacitor dielectric layer may be deposited on the seventh plate layer. The seventh capacitor dielectric layer may be a high-k dielectric layer same or different from the first, second, third, fourth, fifth, and/or the sixth capacitor dielectric layer. The deposited seventh plate layer and the seventh capacitor dielectric layer may be patterned to form the seventh plate 317 and the seventh capacitor dielectric 327. As seen, the seventh plate 317 and the seventh capacitor dielectric 327 may be formed to cover the edge of the third side. In this top view, all of the fifth capacitor dielectric 325 may be obscured. Also, the edge of the fourth side of the sixth capacitor dielectric 326 may be viewable and the rest may be obscured by the seventh capacitor dielectric 327.

FIG. 5H illustrates a stage in which an eighth plate layer may be deposited on the seventh capacitor dielectric 327. The eighth plate layer may be a metal layer same or different from the first, second, third, fourth, fifth, sixth and/or the seventh plate layer. The deposited eighth plate layer may be patterned to form the eighth plate 318. As seen, the eighth plate 318 may be formed to cover the edge of the fourth side. In this top view, all of the sixth capacitor dielectric 326 may be obscured. Also, the edge of the third side of the seventh capacitor dielectric 327 may be viewable and the rest may be obscured by the eighth plate 318.

FIG. 5H also illustrates forming the first, second, third, and fourth vias 331, 332, 333, 334 and the first, second, third, and fourth contacts 341, 342, 343, 344. In one aspect, this may be performed by filling in the trench with more IMD 371 materials, etching to form via and contact patterns, and filling in the via and contact patterns with metals.

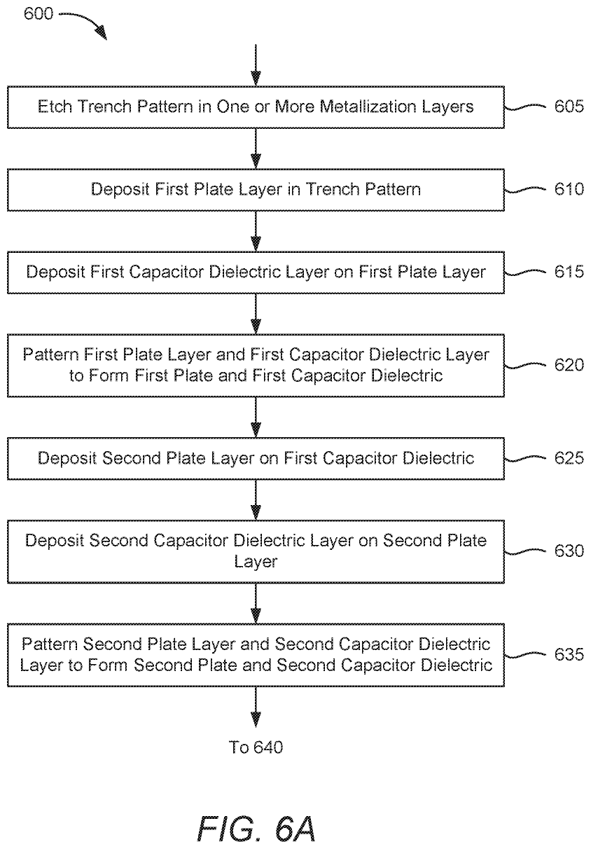

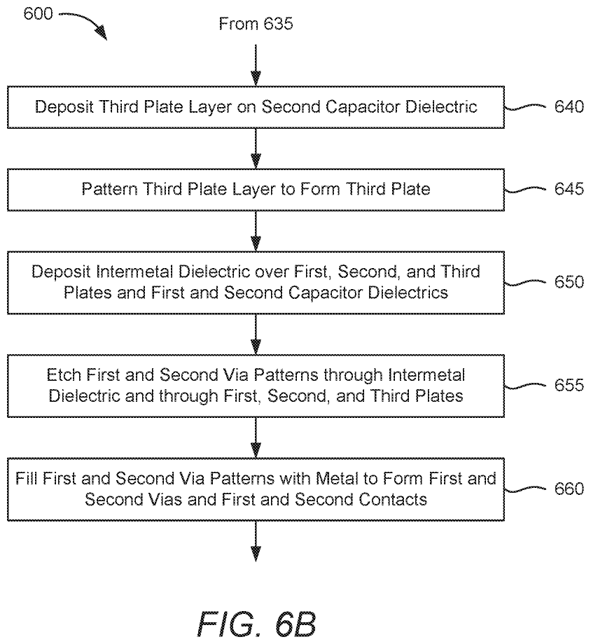

FIGS. 6A and 6B illustrate a flow chart of an example method 600 to fabricate a 3D MIM capacitor, such as the MIM capacitors 200A, 200B and variants, in accordance with one or more aspects of the disclosure.

In block 605, a trench pattern 410 may be etched in one or more metallization layers 270. Block 605 may correspond to the fabrication illustrated in FIG. 4A.

In block 610 a first plate layer may be deposited in the trench pattern 410. In block 615, a first capacitor dielectric layer may be deposited on the first plate layer. In block 620, the first plate layer and the first capacitor dielectric layer may be patterned to form the first plate 211 and the first capacitor dielectric 221. Blocks 610, 615, 620 may correspond to the fabrication stage illustrated in FIG. 4B.

In block 625 a second plate layer may be deposited on the first capacitor dielectric. In block 630, a second capacitor dielectric layer may be deposited on the second plate layer. In block 635, the second plate layer and the second capacitor dielectric layer may be patterned to form the second plate 212 and the second capacitor dielectric 222. Blocks 625, 630, 635 may correspond to the fabrication stage illustrated in FIG. 4C.

In block 640, a third plate layer may be deposited on the second capacitor dielectric. In block 645, the third plate layer may be patterned to form the third plate 213. Blocks 640, 640 may correspond to the fabrication stage illustrated in FIG. 4D.

In block 650, additional IMD 271 may be deposited over the first, second, and third plates 211, 212, 213 and over the first and second capacitor dielectrics 221, 222. In block 655, first and second via patterns 431, 432 as well as first and second contact patterns 441, 442 may be etched in the one or more metallization layers 270. Blocks 650, 655 may correspond to the fabrication stage illustrated in FIG. 4E.

In block 660, the first and second via patterns 431, 432 as well as the first and second contact patterns 441, 442 may be filled with metal to form the first and second via patterns 431, 432 as well as the first and second contact patterns 441, 442. Block 660 may correspond to the fabrication stage illustrated in FIG. 4F.

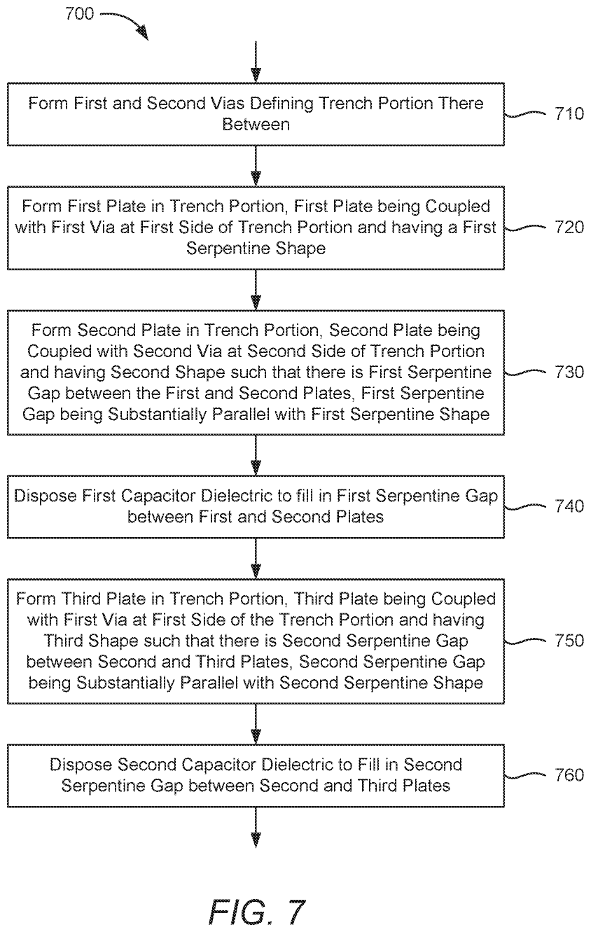

FIG. 7 illustrates a flow chart of another example method 700 to fabricate a 3D MIM capacitor, such as the MIM capacitors 200A, 200B and variants, in accordance with one or more aspects of the disclosure. Method 700 may be viewed as a generalization of method 600. Alternatively, method 600 may be viewed as a particular implementation of method 700.

In block 710, first and second vias 231, 232 may be formed, e.g., in one or more metallization layers 270. The first and second vias 231, 232 may define a trench portion 210.

In block 720, a first plate 211 may be formed in the trench portion 210. The first plate 211 may be coupled with the first via 231 at a first side of the trench portion 210. The first plate 211 may have a first serpentine shape.

In block 730, a second plate 212 may be formed in the trench portion 210. The second plate 212 may be coupled with the second via 232 at a second side of the trench portion. The second plate 212 may have a second shape such that there is a first serpentine gap between the first and second plates 211, 212. The first serpentine gap may be substantially parallel with the first serpentine shape of the first plate 211. In an aspect, the second shape may be a second serpentine shape that is also substantially parallel with the first serpentine shape. In an aspect, the first via 231 may be formed to penetrate the first plate 211. Alternatively or in addition thereto, the second via 232 may be formed to penetrate the second plate 212.

In block 740, a first capacitor dielectric 221 may fill in the first serpentine gap between the first and second plates 211, 212.

In an aspect, blocks 605 (etching trench pattern 410), 610 (depositing first plate layer), 615 (depositing first capacitor dielectric layer), 620 (patterning first plate layer and first capacitor dielectric layer), 625 (depositing second plate layer), 635 (patterning second plate layer), 650 (depositing IMD layer), 655 (etching via and contact patterns), and 660 (filling via and contact patterns) of FIGS. 6A, 6B may be viewed as an example of implementing blocks 710 (forming first and second vias), 720 (forming first plate), 730 (forming second plate), 740 (disposing first capacitor dielectric to fill in first serpentine gap) of FIG. 7.

In block 750, a third plate 213 may be formed in the trench portion 210. The third plate 213 may be coupled with the first via 231 at the first side of the trench portion. The third plate may also have a third shape such that there is a second serpentine gap between the second and third plates 212, 213. The second serpentine gap may be substantially parallel with the second serpentine shape. In an aspect, the third plate 213 may comprise one or more third extensions 213b extending into one or more wells formed by the second plate 212. In an aspect, the first via 231 may be formed to penetrate the third plate 213.

In block 760, a second capacitor dielectric 222 may fill in the second serpentine gap between the second and third plates 212, 213.

In an aspect, blocks 630 (depositing second capacitor dielectric layer), 635 (patterning second capacitor dielectric layer), 640 (depositing third plate layer), 645 (patterning third plate layer) of FIGS. 6A, 6B may be viewed as an example of implementing blocks 750 (forming third plate), 760 (disposing second capacitor dielectric to fill in second serpentine gap) of FIG. 7.

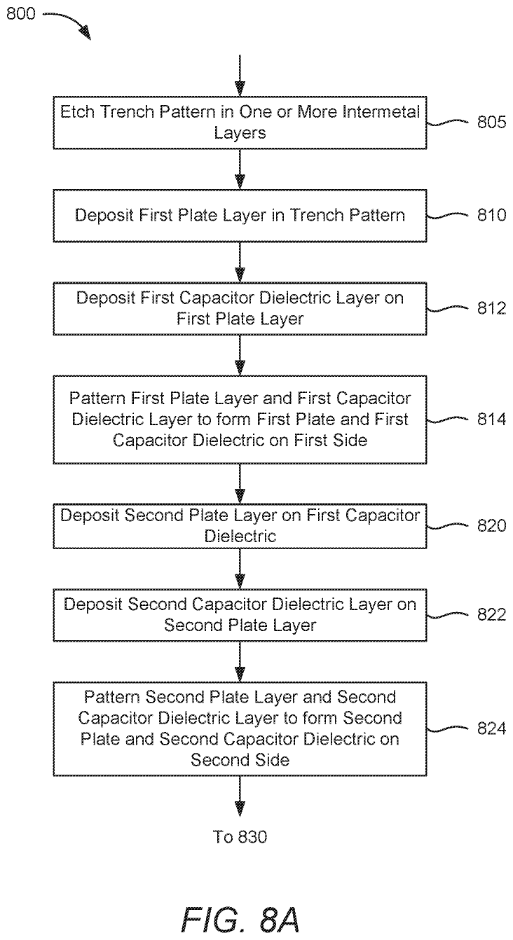

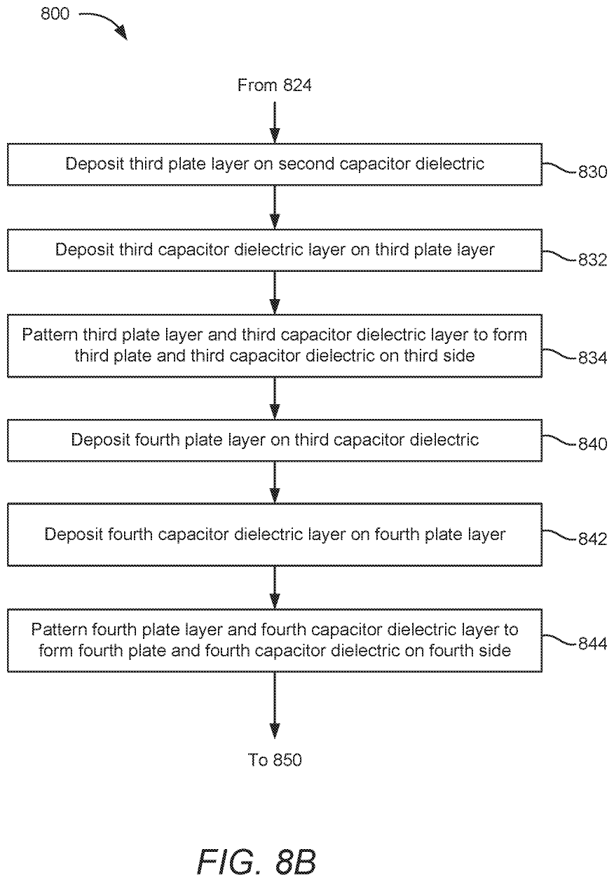

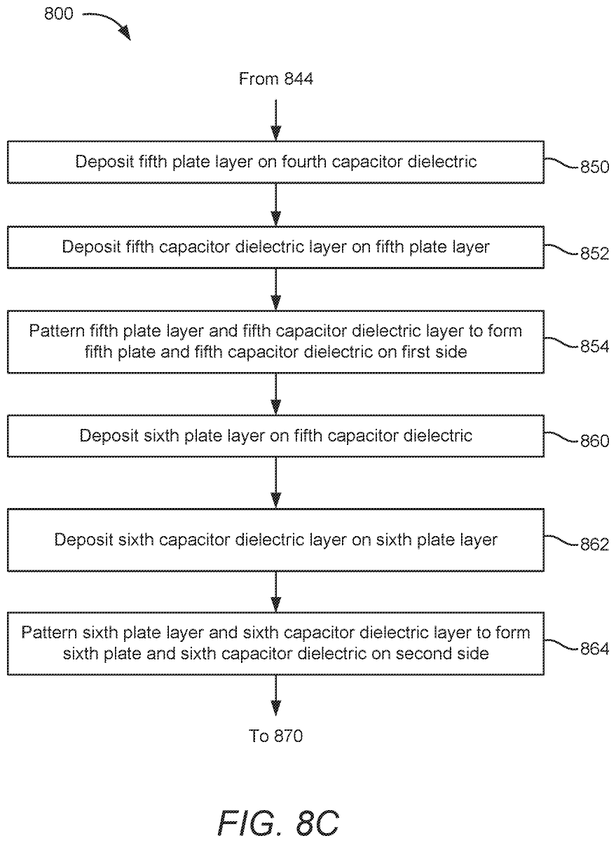

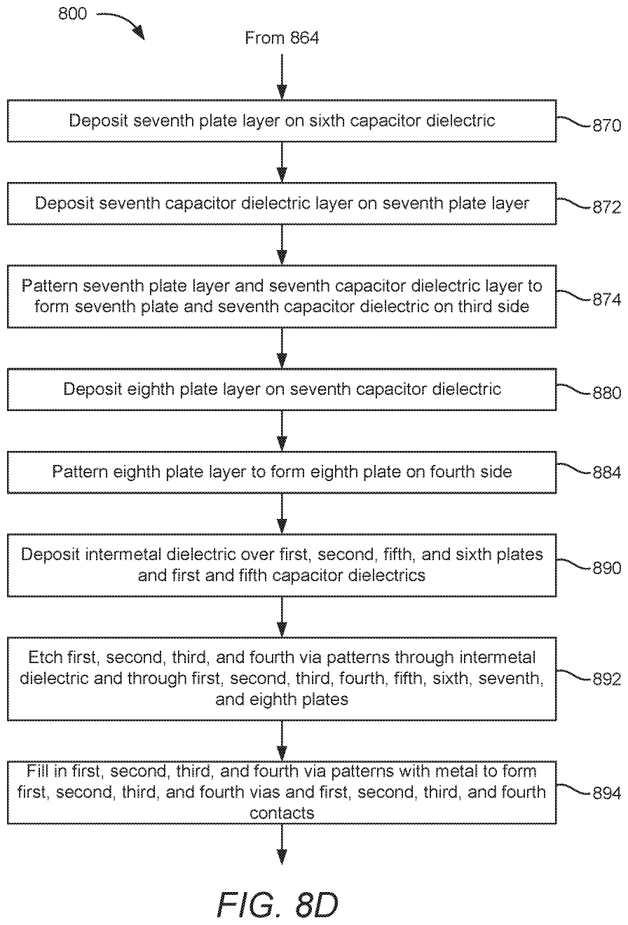

FIGS. 8A-8D illustrates a flow chart of an example method 800 to fabricate a 3D MIM capacitor, such as the MIM capacitor 300 and variants, in accordance with one or more aspects of the disclosure.

In block 805, a trench pattern may be etched in one or more metallization layers 370. In block 810, a first plate layer may be deposited in the trench pattern. In block 812, a first capacitor dielectric layer may be deposited on the first plate layer. In block 814, the first plate layer and the first capacitor dielectric layer may be patterned to form the first plate 311 and the first capacitor dielectric 321. Blocks 805, 810, 812, 814 may correspond to the fabrication stage illustrated in FIG. 5A.

In block 820, a second plate layer may be deposited on the first capacitor dielectric 321. In block 822, a second capacitor dielectric layer may be deposited on the second plate layer. In block 824, the second plate layer and the second capacitor dielectric layer may be patterned to form the second plate 312 and the second capacitor dielectric 322. Blocks 820, 822, 824 may correspond to the fabrication stage illustrated in FIG. 5B.

In block 830, a third plate layer may be deposited on the second capacitor dielectric 322. In block 832, a third capacitor dielectric layer may be deposited on the third plate layer. In block 834, the third plate layer and the third capacitor dielectric layer may be patterned to form the third plate 313 and the third capacitor dielectric 323. Blocks 830, 832, 834 may correspond to the fabrication stage illustrated in FIG. 5C.

In block 840, a fourth plate layer may be deposited on the third capacitor dielectric 323. In block 842, a fourth capacitor dielectric layer may be deposited on the fourth plate layer. In block 844, the fourth plate layer and the fourth capacitor dielectric layer may be patterned to form the fourth plate 314 and the fourth capacitor dielectric 324. Blocks 840, 842, 844 may correspond to the fabrication stage illustrated in FIG. 5D.

In block 850, a fifth plate layer may be deposited on the fourth capacitor dielectric 324. In block 852, a fifth capacitor dielectric layer may be deposited on the fifth plate layer. In block 854, the fifth plate layer and the fifth capacitor dielectric layer may be patterned to form the fifth plate 315 and the fifth capacitor dielectric 325. Blocks 850, 852, 854 may correspond to the fabrication stage illustrated in FIG. 5E.

In block 860, a sixth plate layer may be deposited on the fifth capacitor dielectric 325. In block 862, a sixth capacitor dielectric layer may be deposited on the sixth plate layer. In block 864, the sixth plate layer and the sixth capacitor dielectric layer may be patterned to form the sixth plate 316 and the sixth capacitor dielectric 326. Blocks 860, 862, 864 may correspond to the fabrication stage illustrated in FIG. 5F.

In block 870, a seventh plate layer may be deposited on the sixth capacitor dielectric 326. In block 872, a seventh capacitor dielectric layer may be deposited on the seventh plate layer. In block 874, the seventh plate layer and the seventh capacitor dielectric layer may be patterned to form the seventh plate 317 and the seventh capacitor dielectric 327. Blocks 870, 872, 874 may correspond to the fabrication stage illustrated in FIG. 5G.

In block 880, an eighth plate layer may be deposited on the seventh capacitor dielectric 327. In block 884, the eighth plate layer may be patterned to form the eighth plate 318. In block 890, additional IMD 371 may be deposited over the first-eighth plates 311-317 and over the first-seventh capacitor dielectrics 321-327. In block 892, first-fourth via patterns as well as first-fourth contact patterns may be formed. In block 894, the via and contact patterns may be filled to form first, second, third, and fourth vias 331, 332, 333, 334 and to form first, second, third, and fourth contacts 341, 342, 343, 344. Blocks 880, 884, 890, 892, 894 may correspond to the fabrication stage illustrated in FIG. 5H.

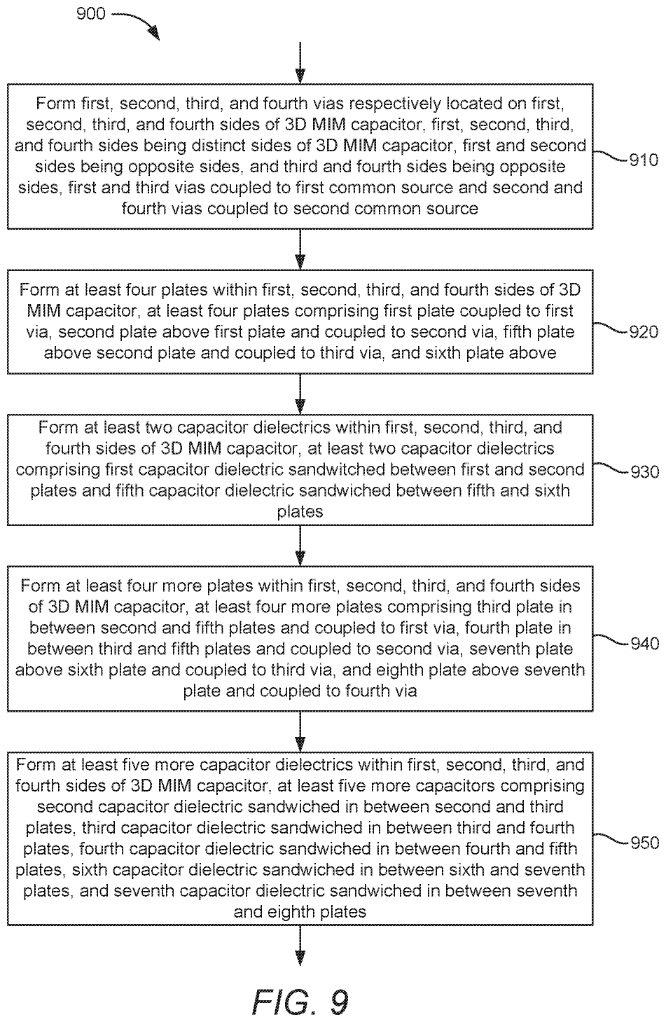

FIG. 9 illustrates a flow chart of another example method 900 to fabricate a 3D MIM capacitor, such as the MIM capacitor 300 and variants, in accordance with one or more aspects of the disclosure. Method 900 may be viewed as a generalization of method 800. Alternatively, method 800 may be viewed as a particular implementation of method 900.

In block 910, first, second, third, and fourth vias 331, 332, 333, 334 may be formed. The first, second, third, and fourth vias 331, 332, 333, 334 may respectively be located on first, second, third, and fourth sides of the 3D MIM capacitor 300. The first, second, third, and fourth sides may be distinct sides of the 3D MIM capacitor. The first and second sides may be opposite sides, and the third and fourth sides may be opposite sides. The first and third vias 331, 333 may be coupled to a first common source (e.g., Vss) and the second and fourth vias 332, 334 may be coupled to a second common source (e.g., Vdd).

In block 920, at least four plates may be formed within the first, second, third, and fourth sides of the 3D MIM capacitor 300. The at least four plates may comprise a first plate 311, a second plate 312 above the first plate 311, a fifth plate 315 above the second plate 312, and a sixth plate 316 above the fifth plate 315. The first plate 311 may be coupled to the first via 331, the second plate 312 may be coupled to the second via 332, the fifth plate 315 may be coupled to the third via 333, and the sixth plate 316 may be coupled to the fourth via 334.

In block 930, at least two capacitor dielectrics may be formed within the first, second, third, and fourth sides of the 3D MIM capacitor 300. The at least two capacitor dielectrics may comprise first and fifth capacitor dielectrics 321, 325. The first capacitor dielectric 321 may be sandwiched between the first and second plates 311, 312. The fifth capacitor dielectric 325 may be sandwiched between the fifth and sixth plates 315, 316.

In an aspect, blocks 805 (etching trench pattern), 810 (depositing first plate layer), 812 (depositing first capacitor dielectric layer), 814 (patterning first plate layer and first capacitor dielectric layer), 820 (depositing second plate layer), 824 (patterning second plate layer), 850 (depositing fifth plate layer), 852 (depositing fifth capacitor dielectric layer), 854 (patterning fifth plate layer and the fifth capacitor dielectric layer), 860 (depositing sixth plate layer), 864 (patterning sixth plate layer), 890 (depositing IMD), 892 (etching via and contact patterns), and 894 (filling via and contact patterns) of FIGS. 8A-8D may be viewed as an example of implementing blocks 910 (forming vias), 920 (forming at least four plates), 930 (forming at least two capacitor dielectrics) of FIG. 9.

In block 940, at least four additional plates may be formed within the first, second, third, and fourth sides of the 3D MIM capacitor 300. The at least four additional plates may comprise a third plate 313 above the second plate 312, a fourth plate 314 between the third and fifth plates 313, 315, a seventh plate 317 above the sixth plate 316, and an eighth plate 318 above the seventh plate 317. The third plate 313 may be coupled to the first via 331, the fourth plate 314 may be coupled to the second via 332, the seventh plate 317 may be coupled to the third via 333, and the eighth plate 318 may be coupled to the fourth via 334.

In block 950, at least five additional capacitor dielectrics may be formed within the first, second, third, and fourth sides of the 3D MIM capacitor 300. The at least five additional capacitor dielectrics may comprise second, third, fourth, sixth, and seventh capacitor dielectrics 322, 323, 324, 326, 327. The second capacitor dielectric 322 may be sandwiched between the second and third plates 312, 313. The third capacitor dielectric 323 may be sandwiched between the third and fourth plates 313, 314. The fourth capacitor dielectric 324 may be sandwiched between the fourth and fifth plates 314, 315. The sixth capacitor dielectric 326 may be sandwiched between the sixth and seventh plates 316, 317. The seventh capacitor dielectric 327 may be sandwiched between the seventh and eighth plates 317, 318.

In an aspect, blocks 822 (depositing second capacitor dielectric layer), 824 (patterning second capacitor dielectric layer), 830 (depositing third plate layer), 832 (depositing third capacitor dielectric layer), 834 (patterning third plate layer and third capacitor dielectric layer), 840 (depositing fourth plate layer), 842 (depositing fourth capacitor dielectric layer), 844 (patterning fourth plate layer and fourth capacitor dielectric layer), 862 (depositing sixth capacitor dielectric layer), 864 (patterning sixth capacitor dielectric layer), 870 (depositing seventh plate layer), 872 (depositing seventh capacitor dielectric layer), 874 (patterning seventh plate layer and seventh capacitor dielectric layer), 880 (depositing eighth plate layer), and 884 (patterning eighth plate layer) of FIGS. 8A-8D may be viewed as an example of implementing blocks 940 (forming at least four additional plates), 950 (forming at least five additional capacitor dielectrics) of FIG. 9.

It will be appreciated that the foregoing fabrication processes and related discussion were provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations. Further, it will be appreciated that the illustrated configurations and descriptions are provided merely to aid in the explanation of the various aspects disclosed herein.

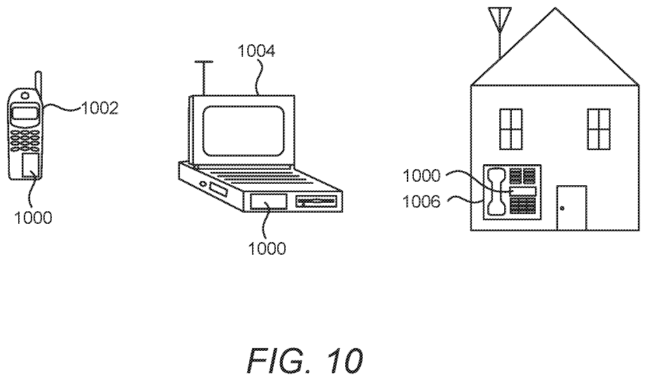

FIG. 10 illustrates various electronic devices that may be integrated with any of the aforementioned 3D MIM capacitors, 200A, 200B, 300 in accordance with various aspects of the disclosure. For example, a mobile phone device 1002, a laptop computer device 1004, and a fixed location terminal device 1006 may each be considered generally user equipment (UE) and may include the 3D MIM capacitors, 200A, 200B, 300 as described herein. The devices 1002, 1004, 1006 illustrated in FIG. 10 are merely exemplary. Other electronic devices may also include the interconnect structures including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

The following provides an overview of examples of the present disclosure:

Example 1: A 3D metal-insulator-metal (MIM) capacitor, comprising: first and second vias defining a trench portion therebetween; a first plate in the trench portion and coupled with the first via at a first side of the trench portion, the first plate having a first serpentine shape; a second plate in the trench portion and coupled with the second via at a second side of the trench portion, the second plate having a second shape such that there is a first serpentine gap between the first and second plates, the first serpentine gap being substantially parallel with the first serpentine shape; and a first capacitor dielectric in the first serpentine gap between the first and second plates, wherein the first via penetrates through the first plate and/or the second via penetrates through the second plate.

Example 2: The 3D MIM capacitor of example 1, wherein the 3D MIM capacitor is formed in one or more metallization layers above a device layer, wherein at least one metallization layer comprises an etch stop layer and an intermetal dielectric (IMD) on the etch stop layer and the device layer comprises one or more transistors, and wherein the 3D MIM capacitor further comprises first and second contacts respectively on and coupled with the first and second vias, top surfaces of the first and second contacts and a top surface of the IMD being substantially coplanar.

Example 3: The 3D MIM capacitor of any of examples 1-2, wherein lower surfaces of the first and second vias and a lower surface of the etch stop layer are substantially coplanar.

Example 4: The 3D MIM capacitor of any of examples 1-3, wherein the first capacitor dielectric is a high-k dielectric and the IMD is a low-k dielectric.

Example 5: The 3D MIM capacitor of any of examples 1-4, wherein the second shape of the second plate is a second serpentine shape substantially parallel with the first serpentine shape, and wherein the 3D MIM capacitor further comprises: a third plate in the trench portion and coupled with the first via at the first side of the trench portion, the third plate having a third shape such that there is a second serpentine gap between the second and third plates, the second serpentine gap being substantially parallel with the second serpentine shape; and a second capacitor dielectric in the second serpentine gap between the second and third plates.

Example 6: The 3D MIM capacitor of example 5, wherein the third plate comprises one or more extensions extending into one or more wells formed by the second plate.

Example 7: The 3D MIM capacitor of any of examples 5-6, wherein the first via penetrates through the third plate.

Example 8: The 3D MIM capacitor of any of examples 1-7, wherein the 3D MIM capacitor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Example 9: A 3D metal-insulator-metal (MIM) capacitor, comprising: first, second, third, and fourth vias respectively located on first, second, third, and fourth sides of the 3D MIM capacitor, the first, second, third, and fourth sides being distinct sides of the 3D MIM capacitor, the first and second sides being opposite sides, and the third and fourth sides being opposite sides; at least four plates within the first, second, third, and fourth sides of the 3D MIM capacitor, the at least four plates comprising: a first plate coupled to the first via; a second plate above the first plate and coupled to the second via; a fifth plate above the second plate and coupled to the third via; and a sixth plate above the fifth plate and coupled to the fourth via; and at least two capacitor dielectrics within the first, second, third, and fourth sides of the 3D MIM capacitor, the at least two capacitor dielectrics comprising: a first capacitor dielectric sandwiched between the first and second plates; and a fifth capacitor dielectric sandwiched between the fifth and sixth plates, wherein the first and third vias are coupled to a first common source and the second and fourth vias are coupled to a second common source.

Example 10: The 3D MIM capacitor of example 9, wherein the first via penetrates through the first plate and/or the second via penetrates through the second plate and/or the third via penetrates through the fifth plate and/or the fourth via penetrates through the sixth plate.

Example 11: The 3D MIM capacitor of any of examples 9-10, wherein the 3D MIM capacitor is formed in one or more metallization layers above a device layer, wherein at least one metallization layer comprises an etch stop layer and an intermetal dielectric (IMD) on the etch stop layer and the device layer comprises one or more transistors, and wherein the 3D MIM capacitor further comprises first, second, third, and fourth contacts respectively on and coupled with the first, second, third, and fourth vias, top surfaces of the first, second, third, and fourth contacts and a top surface of the IMD being substantially coplanar.

Example 12: The 3D MIM capacitor of any of examples 9-11, wherein lower surfaces of the first, second, third, and fourth vias and a lower surface of the etch stop layer are substantially coplanar.

Example 13: The 3D MIM capacitor of any of examples 9-12, wherein the first capacitor dielectric sandwiched between the first and second plates and/or the fifth capacitor dielectric sandwiched between the fifth and sixth plates are high-k dielectrics, and the IMD is a low-k dielectric.

Example 14: The 3D MIM capacitor of any of examples 9-13, wherein the one or more metallization layers comprise a first metallization layer and a second metallization layer on the first metallization layer, wherein the first and second plates and the first capacitor dielectric are formed in the first metallization layer, and wherein the fifth and sixth plates and the fifth capacitor dielectric are formed in the second metallization layer.

Example 15: The 3D MIM capacitor of any of examples 11-14, further comprising at least four additional plates within the first, second, third, and fourth sides of the 3D MIM capacitor, the at least four additional plates comprising: a third plate above the second plate and coupled to the first via; a fourth plate between the third and fifth plates and coupled to the second via; a seventh plate above the sixth plate and coupled to the third via; and an eighth plate above the seventh plate and coupled to the fourth via; and at least five more capacitor dielectrics within the first, second, third, and fourth sides of the 3D MIM capacitor, the at least five more capacitor dielectrics comprising: a second capacitor dielectric sandwiched between the second and third plates; a third capacitor dielectric sandwiched between the third and fourth plates; a fourth capacitor dielectric sandwiched between the fourth and fifth plates; a sixth capacitor dielectric sandwiched between the sixth and seventh plates; and a seventh capacitor dielectric sandwiched between the seventh and eighth plates.

Example 16: The 3D MIM capacitor of example 15, wherein the first via penetrates through the third plate and/or the second via penetrates through the fourth plate and/or the third via penetrates through the seventh plate and/or the fourth via penetrates through the eighth plate.

Example 17: The 3D MIM capacitor of any of examples 15-16, wherein the one or more metallization layers comprise a first metallization layer and a second metallization layer on the first metallization layer, wherein the first, second, third, and fourth plates and the first, second, and third capacitor dielectrics are formed in the first metallization layer, and wherein the fifth, sixth, seventh, and eighth plates and the fifth, sixth, and seventh capacitor dielectrics are formed in the second metallization layer.

Example 18: The 3D MIM capacitor of any of examples 9-17, wherein the 3D MIM capacitor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Example 19: A method of fabricating a 3D metal-insulator-metal (MIM) capacitor, the method comprising: forming first and second vias defining a trench portion therebetween; forming a first plate in the trench portion, the first plate being coupled with the first via at a first side of the trench portion and having a first serpentine shape; forming a second plate in the trench portion, the second plate being coupled with the second via at a second side of the trench portion and having a second shape such that there is a first serpentine gap between the first and second plates, the first serpentine gap being substantially parallel with the first serpentine shape; and disposing a first capacitor dielectric to fill in the first serpentine gap between the first and second plates, wherein the first via is formed to penetrate through the first plate and/or the second via is formed to penetrate through the second plate.

Example 20: The method of example 19, wherein the 3D MIM capacitor is formed in one or more metallization layers above a device layer, wherein at least one metallization layer comprises an etch stop layer and an intermetal dielectric (IMD) on the etch stop layer and the device layer comprises one or more transistors, and wherein the 3D MIM capacitor further comprises first and second contacts respectively on and coupled with the first and second vias, top surfaces of the first and second contacts and a top surface of the IMD being substantially coplanar.

Example 21: The method of any of examples 19-20, wherein lower surfaces of the first and second vias and a lower surface of the etch stop layer are substantially coplanar.

Example 22: The method of any of examples 19-21, wherein the first capacitor dielectric is a high-k dielectric and the IMD is a low-k dielectric.

Example 23: The method of any of examples 19-22, wherein forming the first and second vias, forming the first plate, forming the second plate, and disposing the first capacitor dielectric comprise: etching a trench pattern in one or more metallization layers; depositing a first plate layer in the trench pattern; depositing a first capacitor dielectric layer on the first plate layer; patterning the first plate layer and the first capacitor dielectric layer to form the first plate and the first capacitor dielectric; depositing a second plate layer on the first capacitor dielectric; patterning the second plate layer to form the second plate; depositing intermetal dielectric (IMD) over the first and second plates and the first capacitor dielectric; etching first and second via patterns through the IMD and through the first and second plates; and filling the first and second via patterns with metal to form the first and second vias.

Example 24: The method of any of examples 19-23, wherein the second shape of the second plate is a second serpentine shape substantially parallel with the first serpentine shape, and wherein the method further comprises: forming a third plate in the trench portion, the third plate being coupled with the first via at the first side of the trench portion and having a third shape such that there is a second serpentine gap between the second and third plates, the second serpentine gap being substantially parallel with the second serpentine shape; and disposing a second capacitor dielectric to fill in the second serpentine gap between the second and third plates.

Example 25: The method of example 24, wherein the third plate comprises one or more extensions extending into one or more wells formed by the second plate.

Example 26: The method of any of examples 24-25, wherein the first via penetrates through the third plate.

Example 27: The method of any of examples 24-26, wherein forming the third plate and disposing the second capacitor dielectric comprise: prior to patterning the second plate layer, depositing a second capacitor dielectric layer on the second plate layer, wherein when the second plate layer is patterned, the second capacitor dielectric layer is also patterned to form the second capacitor dielectric; and prior to depositing the IMD: depositing a third plate layer on the second capacitor dielectric; and patterning the third plate layer to form the third plate, wherein when the IMD is deposited, it is also deposited over the second capacitor dielectric and the third plate, and wherein when the first and second via patterns are etched, the first via pattern is also etched through the third plate.

Example 28: A method of fabricating a 3D metal-insulator-metal (MIM) capacitor, the method comprising: forming first, second, third, and fourth vias respectively located on first, second, third, and fourth sides of the 3D MIM capacitor, the first, second, third, and fourth sides being distinct sides of the 3D MIM capacitor, the first and second sides being opposite sides, and the third and fourth sides being opposite sides; forming at least four plates within the first, second, third, and fourth sides of the 3D MIM capacitor, the at least four plates comprising: a first plate coupled to the first via; a second plate above the first plate and coupled to the second via; a fifth plate above the second plate and coupled to the third via; and a sixth plate above the fifth plate and coupled to the fourth via; and forming at least two capacitor dielectrics within the first, second, third, and fourth sides of the 3D MIM capacitor, the at least two capacitor dielectrics comprising: a first capacitor dielectric sandwiched between the first and second plates; and a fifth capacitor dielectric sandwiched between the fifth and sixth plates, wherein the first and third vias are coupled to a first common source and the second and fourth vias are coupled to a second common source.

Example 29: The method of example 28, wherein the first via penetrates through the first plate and/or the second via penetrates through the second plate and/or the third via penetrates through the fifth plate and/or the fourth via penetrates through the sixth plate.

Example 30: The method of any of examples 28-29, wherein the 3D MIM capacitor is formed in one or more metallization layers above a device layer, wherein at least one metallization layer comprises an etch stop layer and an intermetal dielectric (IMD) on the etch stop layer and the device layer comprises one or more transistors, and wherein the 3D MIM capacitor further comprises first, second, third, and fourth contacts respectively on and coupled with the first, second, third, and fourth vias, top surfaces of the first, second, third, and fourth contacts and a top surface of the IMD being substantially coplanar.

Example 31: The method of example 30, wherein lower surfaces of the first, second, third, and fourth vias and a lower surface of the etch stop layer are substantially coplanar.

Example 32: The method of any of examples 30-31, wherein the first capacitor dielectric sandwiched between the first and second plates and/or the fifth capacitor dielectric sandwiched between the fifth and sixth plates are high-k dielectrics, and the IMD is a low-k dielectric.

Example 33, The method of any of examples 30-32, wherein the one or more metallization layers comprise a first metallization layer and a second metallization layer on the first metallization layer, wherein the first and second plates and the first capacitor dielectric are formed in the first metallization layer, and wherein the fifth and sixth plates and the fifth capacitor dielectric are formed in the second metallization layer.

Example 34: The method of any of examples 28-33, wherein forming the first, second, third, and fourth vias, forming the at least four plates, and forming the at least two capacitor dielectrics comprise: etching a trench pattern in one or more metallization layers; depositing a first plate layer in the trench pattern; depositing a first capacitor dielectric layer on the first plate layer; patterning the first plate layer and the first capacitor dielectric layer to form the first plate and the first capacitor dielectric; depositing a second plate layer on the first capacitor dielectric; patterning the second plate layer to form the second plate; depositing a fifth plate layer over the second plate layer; depositing a fifth capacitor dielectric layer on the fifth plate layer; patterning the fifth plate layer and the fifth capacitor dielectric layer to form the fifth plate and the fifth capacitor dielectric; depositing a sixth plate layer on the fifth capacitor dielectric; patterning the sixth plate layer to form the sixth plate; depositing an intermetal dielectric (IMD) over the first, second, fifth, and sixth plates and the first and fifth capacitor dielectrics; etching first, second, third, and fourth via patterns through the IMD and through the first, second, fifth, and sixth plates; and filling the first, second, third, and fourth via patterns with metal to form the first, second, third, and fourth vias.

Example 35: The method of any of examples 28-34, further comprising: forming at least four additional plates within the first, second, third, and fourth sides of the 3D MIM capacitor, the at least four additional plates comprising: a third plate above the second plate and coupled to the first via; a fourth plate between the third and fifth plates and coupled to the second via; a seventh plate above the sixth plate and coupled to the third via; and an eighth plate above the seventh plate and coupled to the fourth via; and forming at least five more capacitor dielectrics within the first, second, third, and fourth sides of the 3D MIM capacitor, the at least five more capacitor dielectrics comprising: a second capacitor dielectric sandwiched between the second and third plates; a third capacitor dielectric sandwiched between the third and fourth plates; a fourth capacitor dielectric sandwiched between the fourth and fifth plates; a sixth capacitor dielectric sandwiched between the sixth and seventh plates; and a seventh capacitor dielectric sandwiched between the seventh and eighth plates.

Example 36: The method of example 35, wherein the first via penetrates through the third plate and/or the second via penetrates through the fourth plate and/or the third via penetrates through the seventh plate and/or the fourth via penetrates through the eighth plate.

Example 37: The method of any of examples 35-36, wherein one or more metallization layers comprise a first metallization layer and a second metallization layer on the first metallization layer, wherein the first, second, third, and fourth plates and the first, second, and third capacitor dielectrics are formed in the first metallization layer, and wherein the fifth, sixth, seventh, and eighth plates and the fifth, sixth, and seventh capacitor dielectrics are formed in the second metallization layer.

Example 38: The method of any of examples 35-37, wherein forming the at least four additional plates and forming the at least five more capacitor dielectrics comprise: prior to patterning the second plate layer, depositing a second capacitor dielectric layer on the second plate layer, wherein when the second plate layer is patterned, the second capacitor dielectric layer is also patterned to form the second capacitor dielectric; prior to depositing the fifth plate layer: depositing a third plate layer on the second capacitor dielectric; depositing a third capacitor dielectric layer on the third plate layer; patterning the third plate layer and the third capacitor dielectric layer to form the third plate and the third capacitor dielectric; depositing a fourth plate layer on the third capacitor dielectric; depositing a fourth capacitor dielectric layer on the fourth plate layer; patterning the fourth plate layer and the fourth capacitor dielectric layer to form the fourth plate and the fourth capacitor dielectric, wherein the fifth plate layer is deposited on the fourth capacitor dielectric; prior to patterning the sixth plate layer, depositing a sixth capacitor dielectric layer on the sixth plate layer, wherein when the sixth plate layer is patterned, the sixth capacitor dielectric layer is also patterned to form the sixth capacitor dielectric; and prior to depositing the IMD: depositing a seventh plate layer on the sixth capacitor dielectric; depositing a seventh capacitor dielectric layer on the seventh plate layer; patterning the seventh plate layer and the seventh capacitor dielectric layer to form the seventh plate and the seventh capacitor dielectric; depositing an eighth plate layer on the seventh capacitor dielectric; and patterning the eighth plate layer to form the eighth plate, wherein when the IMD is deposited, it is also deposited over the at least four additional plates and over the at least five more capacitor dielectrics, and wherein when the first, second, third, and fourth via patterns are etched, the first via pattern is also etched through the third plate, the second via pattern is also etched through the fourth plate, the third via pattern is also etched through the seventh plate, and the fourth via pattern is also etched through the eighth plate.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A 3D metal-insulator-metal (MIM) capacitor, comprising:
first and second vias defining a trench portion therebetween;
a first plate in the trench portion and coupled with the first via at a first side of the trench portion, the first plate having a first serpentine shape;
a second plate in the trench portion and coupled with the second via at a second side of the trench portion, the second plate having a second shape such that there is a first serpentine gap between the first and second plates, the first serpentine gap being substantially parallel with the first serpentine shape; and
a first capacitor dielectric in the first serpentine gap between the first and second plates,
wherein the first via penetrates through the first plate and/or the second via penetrates through the second plate.

2. The 3D MIM capacitor of claim 1,
wherein the 3D MIM capacitor is formed in one or more metallization layers above a device layer,
wherein at least one metallization layer comprises an etch stop layer and an intermetal dielectric (IMD) on the etch stop layer and the device layer comprises one or more transistors, and
wherein the 3D MIM capacitor further comprises first and second contacts respectively on and coupled with the first and second vias, top surfaces of the first and second contacts and a top surface of the IMD being substantially coplanar.

3. The 3D MIM capacitor of claim 2, wherein lower surfaces of the first and second vias and a lower surface of the etch stop layer are substantially coplanar.

4. The 3D MIM capacitor of claim 2, wherein the first capacitor dielectric is a high-k dielectric and the IMD is a low-k dielectric.

5. The 3D MIM capacitor of claim 1,
wherein the second shape of the second plate is a second serpentine shape substantially parallel with the first serpentine shape, and
wherein the 3D MIM capacitor further comprises:
a third plate in the trench portion and coupled with the first via at the first side of the trench portion, the third plate having a third shape such that there is a second serpentine gap between the second and third plates, the second serpentine gap being substantially parallel with the second serpentine shape; and
a second capacitor dielectric in the second serpentine gap between the second and third plates.

6. The 3D MIM capacitor of claim 5, wherein the third plate comprises one or more extensions extending into one or more wells formed by the second plate.

7. The 3D MIM capacitor of claim 5, wherein the first via penetrates through the third plate.

8. The 3D MIM capacitor of claim 1, wherein the 3D MIM capacitor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

9. A 3D metal-insulator-metal (MIM) capacitor, comprising:
first, second, third, and fourth vias respectively located on first, second, third, and fourth sides of the 3D MIM capacitor, the first, second, third, and fourth sides being distinct sides of the 3D MIM capacitor, the first and second sides being opposite sides, and the third and fourth sides being opposite sides;
at least four plates within the first, second, third, and fourth sides of the 3D MIM capacitor, the at least four plates comprising:
a first plate coupled to the first via;
a second plate above the first plate and coupled to the second via;
a fifth plate above the second plate and coupled to the third via; and
a sixth plate above the fifth plate and coupled to the fourth via; and
at least two capacitor dielectrics within the first, second, third, and fourth sides of the 3D MIM capacitor, the at least two capacitor dielectrics comprising:
a first capacitor dielectric sandwiched between the first and second plates; and
a fifth capacitor dielectric sandwiched between the fifth and sixth plates,
wherein the first and third vias are coupled to a first common source and the second and fourth vias are coupled to a second common source.

10. The 3D MIM capacitor of claim 9, wherein the first via penetrates through the first plate and/or the second via penetrates through the second plate and/or the third via penetrates through the fifth plate and/or the fourth via penetrates through the sixth plate.

11. The 3D MIM capacitor of claim 9,
wherein the 3D MIM capacitor is formed in one or more metallization layers above a device layer,
wherein at least one metallization layer comprises an etch stop layer and an intermetal dielectric (IMD) on the etch stop layer and the device layer comprises one or more transistors, and
wherein the 3D MIM capacitor further comprises first, second, third, and fourth contacts respectively on and coupled with the first, second, third, and fourth vias, top surfaces of the first, second, third, and fourth contacts and a top surface of the IMD being substantially coplanar.

12. The 3D MIM capacitor of claim 11, wherein lower surfaces of the first, second, third, and fourth vias and a lower surface of the etch stop layer are substantially coplanar.

13. The 3D MIM capacitor of claim 11, wherein the first capacitor dielectric sandwiched between the first and second plates and/or the fifth capacitor dielectric sandwiched between the fifth and sixth plates are high-k dielectrics, and the IMD is a low-k dielectric.

14. The 3D MIM capacitor of claim 11,
wherein the one or more metallization layers comprise a first metallization layer and a second metallization layer on the first metallization layer,
wherein the first and second plates and the first capacitor dielectric are formed in the first metallization layer, and
wherein the fifth and sixth plates and the fifth capacitor dielectric are formed in the second metallization layer.

15. The 3D MIM capacitor of claim 11, further comprising:
at least four additional plates within the first, second, third, and fourth sides of the 3D MIM capacitor, the at least four additional plates comprising:
a third plate above the second plate and coupled to the first via;
a fourth plate between the third and fifth plates and coupled to the second via;
a seventh plate above the sixth plate and coupled to the third via; and
an eighth plate above the seventh plate and coupled to the fourth via; and
at least five more capacitor dielectrics within the first, second, third, and fourth sides of the 3D MIM capacitor, the at least five more capacitor dielectrics comprising:
a second capacitor dielectric sandwiched between the second and third plates;
a third capacitor dielectric sandwiched between the third and fourth plates;
a fourth capacitor dielectric sandwiched between the fourth and fifth plates;
a sixth capacitor dielectric sandwiched between the sixth and seventh plates; and
a seventh capacitor dielectric sandwiched between the seventh and eighth plates.

16. The 3D MIM capacitor of claim 15, wherein the first via penetrates through the third plate and/or the second via penetrates through the fourth plate and/or the third via penetrates through the seventh plate and/or the fourth via penetrates through the eighth plate.

17. The 3D MIM capacitor of claim 15,
wherein the one or more metallization layers comprise a first metallization layer and a second metallization layer on the first metallization layer,
wherein the first, second, third, and fourth plates and the first, second, and third capacitor dielectrics are formed in the first metallization layer, and
wherein the fifth, sixth, seventh, and eighth plates and the fifth, sixth, and seventh capacitor dielectrics are formed in the second metallization layer.

18. The 3D MIM capacitor of claim 9, wherein the 3D MIM capacitor is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

19. A method of fabricating a 3D metal-insulator-metal (MIM) capacitor, the method comprising:
forming first and second vias defining a trench portion therebetween;
forming a first plate in the trench portion, the first plate being coupled with the first via at a first side of the trench portion and having a first serpentine shape;
forming a second plate in the trench portion, the second plate being coupled with the second via at a second side of the trench portion and having a second shape such that there is a first serpentine gap between the first and second plates, the first serpentine gap being substantially parallel with the first serpentine shape; and
disposing a first capacitor dielectric to fill in the first serpentine gap between the first and second plates,
wherein the first via is formed to penetrate through the first plate and/or the second via is formed to penetrate through the second plate.

20. The method of claim 19,
wherein the 3D MIM capacitor is formed in one or more metallization layers above a device layer,
wherein at least one metallization layer comprises an etch stop layer and an intermetal dielectric (IMD) on the etch stop layer and the device layer comprises one or more transistors, and
wherein the 3D MIM capacitor further comprises first and second contacts respectively on and coupled with the first and second vias, top surfaces of the first and second contacts and a top surface of the IMD being substantially coplanar.

21. The method of claim 20, wherein lower surfaces of the first and second vias and a lower surface of the etch stop layer are substantially coplanar.

22. The method of claim 20, wherein the first capacitor dielectric is a high-k dielectric and the IMD is a low-k dielectric.

23. The method of claim 19, wherein forming the first and second vias, forming the first plate, forming the second plate, and disposing the first capacitor dielectric comprise:
etching a trench pattern in one or more metallization layers;
depositing a first plate layer in the trench pattern;
depositing a first capacitor dielectric layer on the first plate layer;
patterning the first plate layer and the first capacitor dielectric layer to form the first plate and the first capacitor dielectric;
depositing a second plate layer on the first capacitor dielectric;
patterning the second plate layer to form the second plate;
depositing intermetal dielectric (IMD) over the first and second plates and the first capacitor dielectric;
etching first and second via patterns through the IMD and through the first and second plates; and
filling the first and second via patterns with metal to form the first and second vias.

24. The method of claim 23,
wherein the second shape of the second plate is a second serpentine shape substantially parallel with the first serpentine shape, and
wherein the method further comprises:
forming a third plate in the trench portion, the third plate being coupled with the first via at the first side of the trench portion and having a third shape such that there is a second serpentine gap between the second and third plates, the second serpentine gap being substantially parallel with the second serpentine shape; and
disposing a second capacitor dielectric to fill in the second serpentine gap between the second and third plates.

25. The method of claim 24, wherein the third plate comprises one or more extensions extending into one or more wells formed by the second plate.

26. The method of claim 24, wherein the first via penetrates through the third plate.

27. The method of claim 24, wherein forming the third plate and disposing the second capacitor dielectric comprise:
prior to patterning the second plate layer, depositing a second capacitor dielectric layer on the second plate layer, wherein when the second plate layer is patterned, the second capacitor dielectric layer is also patterned to form the second capacitor dielectric; and
prior to depositing the IMD:
depositing a third plate layer on the second capacitor dielectric; and
patterning the third plate layer to form the third plate,
wherein when the IMD is deposited, it is also deposited over the second capacitor dielectric and the third plate, and
wherein when the first and second via patterns are etched, the first via pattern is also etched through the third plate.

28. A method of fabricating a 3D metal-insulator-metal (MIM) capacitor, the method comprising:
forming first, second, third, and fourth vias respectively located on first, second, third, and fourth sides of the 3D MIM capacitor, the first, second, third, and fourth sides being distinct sides of the 3D MIM capacitor, the first and second sides being opposite sides, and the third and fourth sides being opposite sides;
forming at least four plates within the first, second, third, and fourth sides of the 3D MIM capacitor, the at least four plates comprising:
a first plate coupled to the first via;
a second plate above the first plate and coupled to the second via;
a fifth plate above the second plate and coupled to the third via; and
a sixth plate above the fifth plate and coupled to the fourth via; and
forming at least two capacitor dielectrics within the first, second, third, and fourth sides of the 3D MIM capacitor, the at least two capacitor dielectrics comprising:
a first capacitor dielectric sandwiched between the first and second plates; and
a fifth capacitor dielectric sandwiched between the fifth and sixth plates,
wherein the first and third vias are coupled to a first common source and the second and fourth vias are coupled to a second common source.

29. The method of claim 28, wherein the first via penetrates through the first plate and/or the second via penetrates through the second plate and/or the third via penetrates through the fifth plate and/or the fourth via penetrates through the sixth plate.

30. The method of claim 28,
wherein the 3D MIM capacitor is formed in one or more metallization layers above a device layer,
wherein at least one metallization layer comprises an etch stop layer and an intermetal dielectric (IMD) on the etch stop layer and the device layer comprises one or more transistors, and
wherein the 3D MIM capacitor further comprises first, second, third, and fourth contacts respectively on and coupled with the first, second, third, and fourth vias, top surfaces of the first, second, third, and fourth contacts and a top surface of the IMD being substantially coplanar.

31. The method of claim 30, wherein lower surfaces of the first, second, third, and fourth vias and a lower surface of the etch stop layer are substantially coplanar.

32. The method of claim 30, wherein the first capacitor dielectric sandwiched between the first and second plates and/or the fifth capacitor dielectric sandwiched between the fifth and sixth plates are high-k dielectrics, and the IMD is a low-k dielectric.

33. The method of claim 30,
wherein the one or more metallization layers comprise a first metallization layer and a second metallization layer on the first metallization layer,
wherein the first and second plates and the first capacitor dielectric are formed in the first metallization layer, and
wherein the fifth and sixth plates and the fifth capacitor dielectric are formed in the second metallization layer.

34. The method of claim 28, wherein forming the first, second, third, and fourth vias, forming the at least four plates, and forming the at least two capacitor dielectrics comprise:
etching a trench pattern in one or more metallization layers;
depositing a first plate layer in the trench pattern;
depositing a first capacitor dielectric layer on the first plate layer;
patterning the first plate layer and the first capacitor dielectric layer to form the first plate and the first capacitor dielectric;
depositing a second plate layer on the first capacitor dielectric;
patterning the second plate layer to form the second plate;
depositing a fifth plate layer over the second plate layer;
depositing a fifth capacitor dielectric layer on the fifth plate layer;
patterning the fifth plate layer and the fifth capacitor dielectric layer to form the fifth plate and the fifth capacitor dielectric;
depositing a sixth plate layer on the fifth capacitor dielectric;
patterning the sixth plate layer to form the sixth plate;
depositing an intermetal dielectric (IMD) over the first, second, fifth, and sixth plates and the first and fifth capacitor dielectrics;
etching first, second, third, and fourth via patterns through the IMD and through the first, second, fifth, and sixth plates; and
filling the first, second, third, and fourth via patterns with metal to form the first, second, third, and fourth vias.

35. The method of claim 34, further comprising:
forming at least four additional plates within the first, second, third, and fourth sides of the 3D MIM capacitor, the at least four additional plates comprising:
a third plate above the second plate and coupled to the first via;
a fourth plate between the third and fifth plates and coupled to the second via;
a seventh plate above the sixth plate and coupled to the third via; and
an eighth plate above the seventh plate and coupled to the fourth via; and
forming at least five more capacitor dielectrics within the first, second, third, and fourth sides of the 3D MIM capacitor, the at least five more capacitor dielectrics comprising:
a second capacitor dielectric sandwiched between the second and third plates;
a third capacitor dielectric sandwiched between the third and fourth plates;
a fourth capacitor dielectric sandwiched between the fourth and fifth plates;
a sixth capacitor dielectric sandwiched between the sixth and seventh plates; and
a seventh capacitor dielectric sandwiched between the seventh and eighth plates.

36. The method of claim 35, wherein the first via penetrates through the third plate and/or the second via penetrates through the fourth plate and/or the third via penetrates through the seventh plate and/or the fourth via penetrates through the eighth plate.

37. The method of claim 35,
wherein one or more metallization layers comprise a first metallization layer and a second metallization layer on the first metallization layer,
wherein the first, second, third, and fourth plates and the first, second, and third capacitor dielectrics are formed in the first metallization layer, and
wherein the fifth, sixth, seventh, and eighth plates and the fifth, sixth, and seventh capacitor dielectrics are formed in the second metallization layer.

38. The method of claim 35, wherein forming the at least four additional plates and forming the at least five more capacitor dielectrics comprise:
prior to patterning the second plate layer, depositing a second capacitor dielectric layer on the second plate layer, wherein when the second plate layer is patterned, the second capacitor dielectric layer is also patterned to form the second capacitor dielectric;
prior to depositing the fifth plate layer:
depositing a third plate layer on the second capacitor dielectric;
depositing a third capacitor dielectric layer on the third plate layer;
patterning the third plate layer and the third capacitor dielectric layer to form the third plate and the third capacitor dielectric;
depositing a fourth plate layer on the third capacitor dielectric;
depositing a fourth capacitor dielectric layer on the fourth plate layer; and
patterning the fourth plate layer and the fourth capacitor dielectric layer to form the fourth plate and the fourth capacitor dielectric, wherein the fifth plate layer is deposited on the fourth capacitor dielectric;
prior to patterning the sixth plate layer, depositing a sixth capacitor dielectric layer on the sixth plate layer, wherein when the sixth plate layer is patterned, the sixth capacitor dielectric layer is also patterned to form the sixth capacitor dielectric; and
prior to depositing the IMD:
depositing a seventh plate layer on the sixth capacitor dielectric;
depositing a seventh capacitor dielectric layer on the seventh plate layer;
patterning the seventh plate layer and the seventh capacitor dielectric layer to form the seventh plate and the seventh capacitor dielectric;
depositing an eighth plate layer on the seventh capacitor dielectric; and
patterning the eighth plate layer to form the eighth plate,
wherein when the IMD is deposited, it is also deposited over the at least four additional plates and over the at least five more capacitor dielectrics, and
wherein when the first, second, third, and fourth via patterns are etched, the first via pattern is also etched through the third plate, the second via pattern is also etched through the fourth plate, the third via pattern is also etched through the seventh plate, and the fourth via pattern is also etched through the eighth plate.
